(19) United States
(12) Patent Application Publication
(10) Pub. No.: US 2015/0333207 A1
(43) Pub. Date: Nov. 19, 2015

(54) SYSTEMS AND METHODS FOR IMPROVED PHOTOVOLTAIC MODULE STRUCTURE

(71) Applicant: DIRECT SOLAR, LLC, Fort Collins, CO (US)

(72) Inventors: Kurt L. Barth, Fort Collins, CO (US); John C. Powerll, Fort Collins, CO (US); Neil Morris, Fort Collins, CO (US); Nader Mahavan, Niwot, CO (US)

(21) Appl. No.: 14/808,941

(22) Filed: Jul. 24, 2015

Related U.S. Application Data
(63) Continuation of application No. 14/299,084, filed on Jun. 9, 2014.
Application No. 14/299,084 is a continuation of application No. 13/847,379, filed on Mar. 19, 2013, now abandoned.
Application No. 13/847,379 is a continuation of application No. 12/392,055, filed on Feb. 24, 2009, now abandoned.
Application No. 12/392,055 is a continuation of application No. 12/392,053, filed on Feb. 24, 2009, now abandoned.

(51) Int. Cl. H01L 31/048; H01L 31/18; H01L 31/052; H01L 31/049

(52) U.S. Cl. CPC H01L 31/0488; H01L 31/049; H01L 31/1876; H01L 31/0525

(57) ABSTRACT

A system and method for improved photovoltaic module structure is described. One embodiment includes a photovoltaic module comprising a front substrate, a photovoltaic structure attached to the front substrate, wherein the photovoltaic structure comprises at least one photovoltaic cell, a back substrate, wherein the back substrate is spaced apart from the photovoltaic structure, and a structural component, wherein the structural component is located between the back substrate and the photovoltaic structure. In some embodiments, the structural component may be configured to provide thermal conduction between the front substrate and the back substrate, and/or the structural component may be configured to retain the front substrate and/or back substrate during breakage.

### CROSS-REFERENCE TO RELATED APPLICATIONS

The present application is a continuation of U.S. patent application Ser. No. 14/299,084, filed Jun. 9, 2014, entitled “Systems and Methods for Improved Photovoltaic Module Structure,” which application is a continuation of U.S. patent application Ser. No. 13/847,379, filed Mar. 19, 2013, entitled “Systems and Methods for Improved Photovoltaic Module Structure,” which application is a continuation of U.S. patent application Ser. No. 12/392,055, filed Feb. 24, 2009, entitled “Systems and Methods for Improved Photovoltaic Module Structure,” and U.S. patent application Ser. No. 12/392,053, filed Feb. 24, 2009, entitled “Systems and Methods for Improved Photovoltaic Module Structure and Encapsulation.”

### FIELD OF THE INVENTION

The present invention relates to photovoltaic modules and methods of fabrication. Specifically the present invention relates to a module structure with improved durability to weathering environments, increased safety if broken and reduced manufacturing costs when compared to the current state of the art.

### BACKGROUND OF THE INVENTION

Photovoltaic modules convert solar energy into electricity through the photovoltaic effect. As such, photovoltaic modules represent a clean source of renewable energy in a global marketplace dominated by traditional fossil-fuel technologies, such as coal-fired and oil-fired power plants. However, to be a major source of energy within the global marketplace, photovoltaic modules must be manufactured as a commodity in quantities and at costs that are competitive with existing fossil fuel technologies.

One such photovoltaic module type that satisfies the requirements for commodity manufacturing is the cadmium telluride (CdTe) photovoltaic module. CdTe photovoltaic modules generally take the form of thin film polycrystalline devices in which CdTe layer is paired with a cadmium sulfide (CdS) layer to form a hetero-junction. Although a variety of vacuum and non-vacuum processes can produce the thin films for a CdTe/CdS photovoltaic module, physical vapor deposition techniques, especially vacuum sublimation deposition of CdTe and CdS thin films, are amenable to the commodity manufacturing of CdTe/CdS photovoltaic modules. For example, vacuum sublimation of CdS and CdTe thin films can result in thin-film deposition rates ten to one hundred times higher than other suitable deposition techniques. Cadmium sulfide/cadmium telluride solar cells can use up to 100 times less semiconductor material than crystalline silicon devices and can be manufactured less expensively.

A process for manufacturing CdS/CdTe modules includes the following steps: 1) cleaning the transparent conducting oxide (TCO) coated glass plate; 2) heating the glass plate; 3) depositing the n-type CdS layer; 4) depositing the p-type CdTe layer; 5) performing a CdCl₂ treatment to improve the CdTe grain structure and electrical properties; 6) forming a p+ low resistance region to improve current collection in the CdTe; 7) scribing the film layers into individual cells; 8) depositing one or more metal layers to form the back electrode metallization; 9) scribing the back electrode metallization to interconnect the cells in series (isolation scribe) to form the photovoltaic structure; 10) providing busses for electrical connection to the photovoltaic structure; 11) affixing a back substrate to sandwich the photovoltaic structure and form the photovoltaic module; 12) encapsulating the photovoltaic module; and 13) attaching external leads.

Cadmium telluride solar cells can be degraded by prolonged exposure to moisture and require effective encapsulation to remain reliable. Typically, CdTe solar cells are deposited on a glass plate with TCO layers. This front substrate, also called a superstrate, faces the sun during operation. Light must pass through the superstrate before being absorbed by the photovoltaic structure. This front substrate is also may be referred to as the top plate or top glass.

To complete the photovoltaic module, a back substrate is affixed to the rear of the module, sandwiching the photovoltaic structure. The back substrate is often a glass plate which is held to the front substrate with different sealants, glues or polymer lamination films. Back substrate can also be polymer or coated metal. With some module construction methods, particularly those using an edge seal around the module perimeter, an open space or gap between may be present between the front substrate and back substrate. Together the back substrate and the polymer adhesive materials form the encapsulation of the photovoltaic module.

Industry standard photovoltaic warranties are for 20 to 25 years. The encapsulation and module structure must resist a number of stresses during transport and operation over the life of the module. Modules are also frequently tested to certification and testing standards such as the American National Standards Institute/Underwriters Laboratories (UL) 1703 and International Electrotechnical Commission (IEC) 61646 and 61730. The module must withstand the testing described in these certification specifications. In order to pass the tests described in these standards, the module encapsulation must protect the photovoltaic structure from moisture and other potential sources of environmental degradation. The front substrate and the back substrate must provide significant mechanical strength to withstand mechanical loading from wind and snow. Additionally, the module must withstand impacts from hail and windblown debris. Photovoltaic devices loose performance with increasing temperature. Effective module encapsulation minimizes the module operating temperature. Photovoltaic module encapsulation methods must be high throughput and low cost to facilitate manufacturing.

If the module does break due to mishandling or extreme impact, it is undesirable for large glass shards to be ejected from the module. These shards could cause human injury and be a potential source for heavy-metal-containing materials to enter the environment. Large arrays of photovoltaic modules can operate at up to 1000 volts. A danger of electric shock or fire exists if, upon breakage in the field, internal busses or leads are exposed. The IEC 61730 and UL 1703 standards specify requirements for module cohesion under catastrophic breakage. Effective photovoltaic module encapsulation systems must maintain sufficient cohesion to prevent the ejection of dangerous glass shards and to offer some protection from high voltage regions. This can be accomplished by either increasing the overall robustness of the module to prevent breakage or by retaining the broken pieces with the module if breakage occurs.

Encapsulation methods described in the prior art for thin film, and in particular CdTe, photovoltaic modules all have limitations in fulfilling requirements described above. The subject invention addresses these limitations, facilitating an increase in reliability and manufacturing efficiency.

Frequently CdTe photovoltaic modules are constructed with front and back substrates made of glass. The front and back glass are laminated together with an ethylene vinyl acetate (EVA) film sheet of nearly identical size as the glass plates. However, the EVA material has poor moisture vapor transmission properties, allowing moisture to permeate into the modules and contact the photovoltaic structure. Additionally, the EVA/moisture interaction enables the formation of acetic acid in the EVA. Acetic acid can degrade and corrode the photovoltaic structure. In an attempt to overcome the poor moisture performance of EVA, strips of lower moisture vapor transmission materials are laminated around the perimeter of the module to reduce moisture ingress. These materials often contain butyl rubber and desiccants. This method is an improvement on EVA only encapsulation and is used in commercial application by companies such as First Solar. However, this method still has limitations. Gaps can be present where the strips join each other. The strip material does not bond as effectively to the glass as EVA and may have bubbles or voids which can facilitate moisture entry into the EVA. The strips may have a lower moisture vapor transmission than the EVA but moisture ingress is not eliminated. The strip material may also degrade due to UV radiation further enabling moisture ingress. When moisture does enter into the panel either through a gap, breach, permeation or strip degradation, the photovoltaic structure will be degraded and corroded by acetic acid.

EVA lamination is a time consuming, batch type manufacturing process. The EVA lamination process includes the following manufacturing steps: 1) first the EVA material is cut and is laid on the front glass plates; 2) the strip seals are carefully positioned; 3) the back glass plate is placed on the stack; 4) this stack is then placed in a lamination machine; 5) vacuum to remove entrapped air; 6) the stack is heated to soften the EVA and initiate cross linking; and 7) pressure is applied to the stack. The vacuum/heat/pressure lamination cycle can take 15 to 20 minutes. In order to maintain production throughput, large vacuum laminators are required. These require significant factory floor space and are expensive.

There have been attempts to develop encapsulation systems to replace EVA lamination. Significant examples will be reviewed; however, all methods have limitations for module reliability or manufacturing efficiency when compared to the subject invention.

Albright et al. describes methods for photovoltaic module encapsulation in U.S. Pat. No. 5,460,660. In this expired patent, a series of designs are shown in which a photovoltaic module is supported in a complex frame and channel arrangement. A front glass plate containing the photovoltaic structure is paired with another back substrate, most often glass. Edge seals are present around the perimeter of the module to impede moisture ingress. A gap exists between the front substrate and back substrate. Desiccant is present between the front and back substrate, completely filling the gap between the sheets in some embodiments. Panel frame and channel supports are provided to absorb vertical forces and impacts. In some embodiments, polymer bumpers are disposed between the glass plates to absorb impact.

The module structure described by Albright et al. is too complex. Industry experience has shown complex frame systems are not needed for reliably handling vertical impact. This complexity adds to the manufacturing and deployment costs. Perimeter edge seals can be effective in sealing a photovoltaic module; however, this patent teaches methods that require too many materials and application steps. Edge spacers, that separate the plates, add cost and bulk to the module. The gap between the plates, created by the relatively large spacers, forms a thermal insulating barrier. The large spacers and the resulting large air gap are similar in function to insulating glass windows and would cause the module to operate at elevated temperatures, reducing performance. Panel supports, positioned inside the gap between the two plates, could be effective at absorbing vertical forces, but are insufficient to allow thermal condition between the plates to cool the module. In the case of breakage, no method of glass shard retention is taught.

Oswald describes methods for photovoltaic module encapsulation in US patent application US 2003/0116185 A1. In this application, the front and back substrate are separated by perimeter edge seals to form the photovoltaic module. In Oswald, a photovoltaic element is exposed to the internal volume which could be desiccated. Oswald teaches that the thin film photovoltaic material is not to be covered or protected inside the sealed volume between the front and back substrate.

The module structure described by Oswald has significant limitations. The gap between the front and back substrate will cause elevated module operating temperatures in a manner similar to an insulated glass window. No means are provided to facilitate thermal conduction between the front and back substrate to lower the operating temperature. If desiccants are disposed in the regions between the front and back substrate, no means of holding or containing the desiccant is described. The lack of internal structures between the front and back substrate will leave the module susceptible to breakage by impact or other mechanical loading. The module design taught in this application is particularly susceptible to ejecting large glass shards and exposing internal structures at elevated voltage upon breakage.

Blieske et al. describes a photovoltaic module design in U.S. Pat. No. 6,673,997 B2. A border seal containing desiccant is used to seal front and back glass plates. This seal material is placed around the perimeter, just inboard of the glass edge. An adhesive is placed around the perimeter between the glass edge and the sealant. Blieske et al. further describe that a liquid casting material can be injected in the gap between the glass plates through tubes.

The module structure described by Blieske has significant limitations. If the optional casting resin is not used, the module will operate at elevated temperatures in a manner similar to an insulated glass window. Without the optional casting resin, large glass shards could be ejected and high voltage regions exposed if the module is broken.

Injecting the resin, as in Blieske, also requires gaps or tubes in the edge seal to inject the liquid and to remove air displaced by the casting medium. These gaps or tubes are unnecessarily complex to implement in a manufacturing environment and significantly degrade the primary module seal. The casting resin will require additional curing in an autoclave. The autoclave cure is a batch process which adds further complexity, inefficiency and cost to the manufacturing process. Adding desiccant to the border seal is unnecessarily complex and could compromise adhesion. Desiccant can be more easily and less expensively placed inside the module. Moisture can penetrate into the module through areas other than the edge, for example, through the back electrical box. If casing resins are used, this moisture will not be readily absorbed by the desiccant in the perimeter seal and will remain to damage the module.

Although present devices are functional, they are not sufficiently accurate or otherwise satisfactory. Accordingly, a system and method are needed to address the shortfalls of present technology and to provide other new and innovative features.

### SUMMARY OF THE INVENTION

Exemplary embodiments of the present invention that are shown in the drawings are summarized below. These and other embodiments are more fully described in the Detailed Description section. It is to be understood, however, that there is no intention to limit the invention to the forms described in this Summary of the Invention or in the Detailed Description. One skilled in the art can recognize that there are numerous modifications, equivalents and alternative constructions that fall within the spirit and scope of the invention as expressed in the claims.

The present invention can provide a system and method for improved photovoltaic module structure. In one exemplary embodiment, the present invention can include a photovoltaic module comprising a front substrate, a photovoltaic structure attached to the front substrate, wherein the photovoltaic structure comprises at least one photovoltaic cell, a back substrate, wherein the back substrate is spaced apart from the photovoltaic structure, and a structural component, wherein the structural component is located between the back substrate and the photovoltaic structure. The structural component may comprise ribbing, foam (e.g., porous foam, corrugated foam, embossed foam, a high density foam, etc.), and/or a solid interlayer. In some embodiments the structural component is configured to connect to at least one of the front substrate and the back substrate. In some embodiments, the structural component is configured to provide thermal conduction between the front substrate and the back substrate, and/or the structural component is configured to retain the front substrate and/or back substrate during breakage.

In another exemplary embodiment, the present invention can include a method for making a photovoltaic module, the method comprising forming a photovoltaic structure on a front substrate, wherein the photovoltaic structure comprises at least one photovoltaic cell, positioning a structural component between the photovoltaic structure and a back substrate, and connecting the back substrate with the front substrate using a seal, wherein the structural component is configured to provide distributed thermal conduction from the front substrate to the back substrate.

In another exemplary embodiment, the present invention can include a photovoltaic module comprising a front substrate, a photovoltaic structure attached to the front substrate, a back substrate, wherein the back substrate is spaced apart from the photovoltaic structure to form a gap, and a structural component, wherein the structural component spans the gap between back substrate and the photovoltaic structure.

As previously stated, the above-described embodiments and implementations are for illustration purposes only. Numerous other embodiments, implementations, and details of the invention are easily recognized by those of skill in the art from the following descriptions and claims.

### BRIEF DESCRIPTION OF THE DRAWINGS

The accompanying drawings, which are incorporated herein and form a part of the specification, illustrate one or more embodiments of the present invention and, together with the description, further serve to explain the principles of the invention and to enable a person skilled in the pertinent art to make and use the invention.

Table 1 lists the drawing reference numbers for the components which are incorporated herein and form a part of the specification. Level 1 indicates a component group. Level 2 indicates a sub-component of the group. Level 3 indicates a specified component part. In the drawings a Level 1 (X000) indicator represents all sublevel components. In the drawings, like reference numbers can indicate identical or functionally similar elements.

TABLE 1
Component Indicator References

| Level 1 | Level 2 | Level 3 | Description | Desiccated |
|---|---|---|---|---|
| 1000 | | | Front Substrate | |
| 2000 | | | Back Substrate | |
| 3000 | | | External Seal Assembly | |
| | 3100 | | Vapor Barrier | |
| | 3200 | | Edge Seal | |
| | 3300 | | Connection Seal | |
| 4000 | | | Photovoltaic Structure | |
| 5000 | | | Buss Bar Assembly | |
| | 5100 | | Buss Bar Collectors | |
| | | 5110 | Anode Edge Collector Buss | |
| | | 5120 | Cathode Edge Collector Buss | |
| | | 5130 | Anode Central Main Buss | |
| | | 5140 | Cathode Central Main Buss | |
| | 5200 | | Buss Assembly Connection | |
| | 5300 | | Buss Assembly Insulator | |
| 6000 | | | Membrane | Optional |
| | 6100 | | Undercoat Membrane | Optional |
| | 6200 | | Overcoat Membrane | Optional |
| 7000 | | | Membrane Reinforcement | |
| | 7100 | | Scrim Sheet Reinforcement | |
| | 7200 | | Mesh Sheet Reinforcement | |
| | 7300 | | Scrim Impregnated | |
| | | | Reinforcement | |
| 8000 | | | Ribbing | Optional |
| 9000 | | | Retention Sheet | Optional |
| | 9100 | | Retention Tape Sheet | |
| | 9200 | | Retention Tape Strips | |
| 10000 | | | Interlayer | Optional |
| | 10100 | | Foam Interlayer | Optional |
| | 10200 | | Structural Interlayer | Optional |
| | 10300 | | Solid Interlayer | Optional |
| | 10400 | | Solid Interlayer Perimeter | Required |

### LIST OF FIGURES

Various objects and advantages and a more complete understanding of the present invention are apparent and more readily appreciated by reference to the following Detailed Description and to the appended claims when taken in conjunction with the accompanying Drawings:

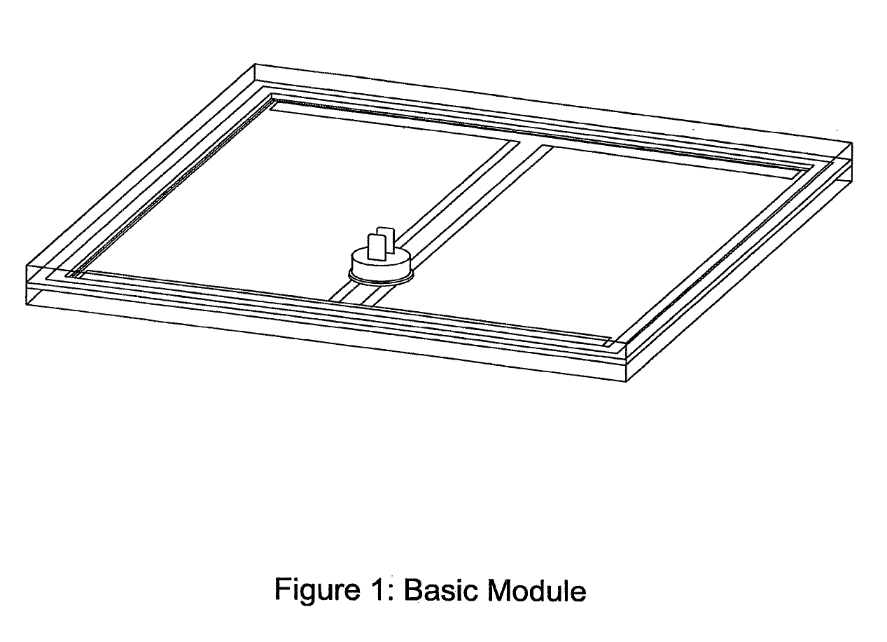

FIG. 1: Basic Module

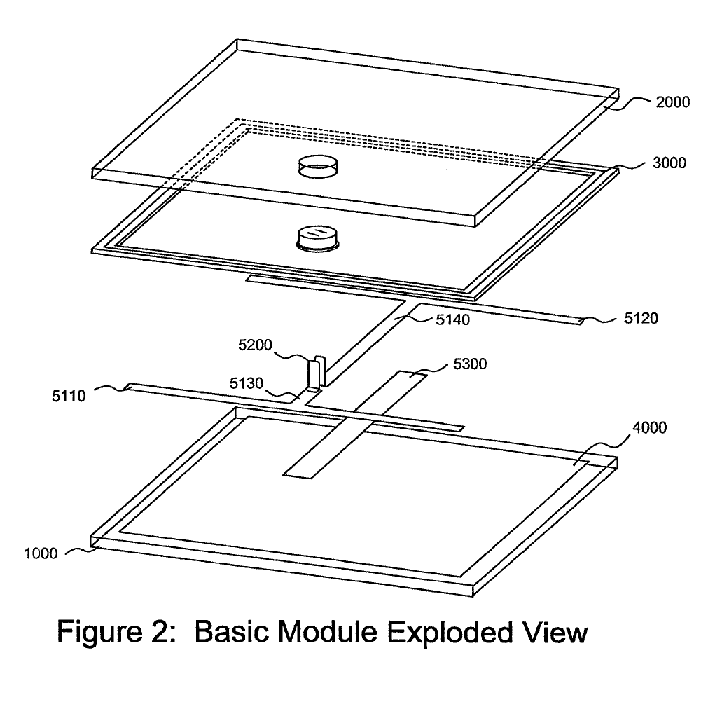

FIG. 2: Basic Module Exploded View

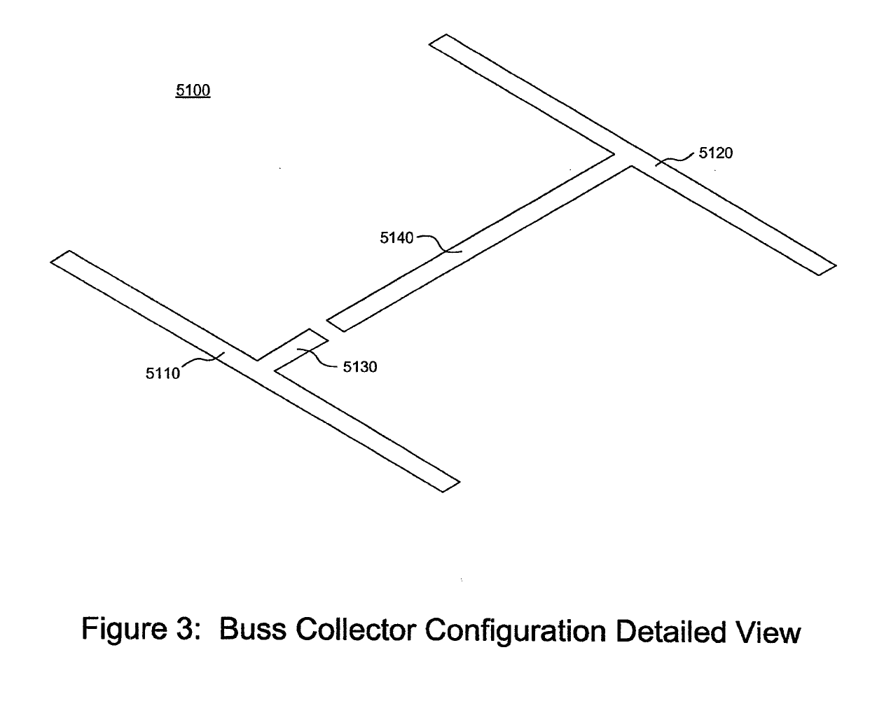

FIG. 3: Buss Collector Configuration Detailed View

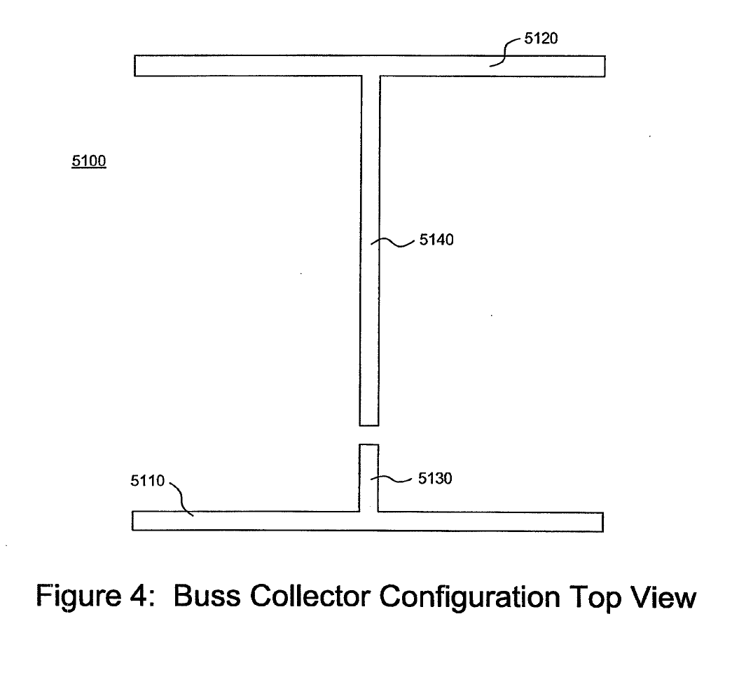

FIG. 4: Buss Collector Configuration Top View

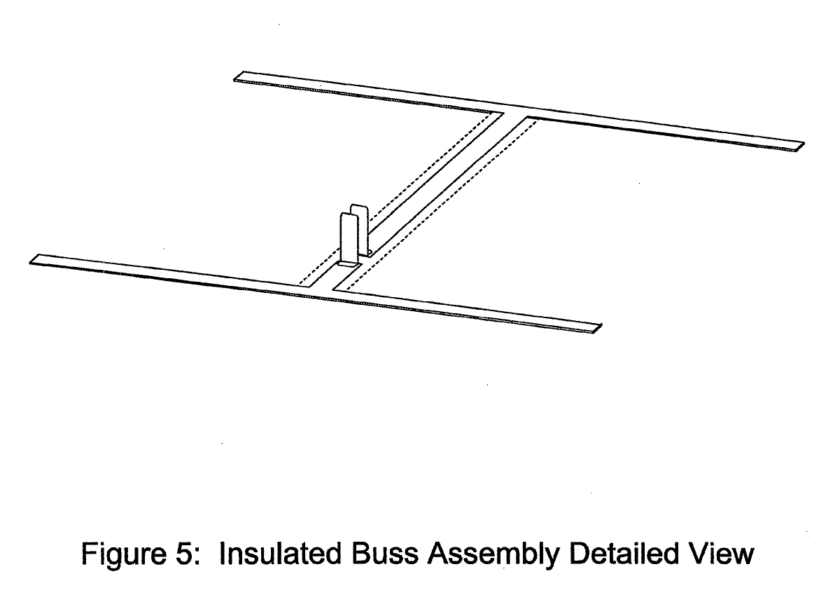

FIG. 5: Insulated Buss Assembly Detailed View

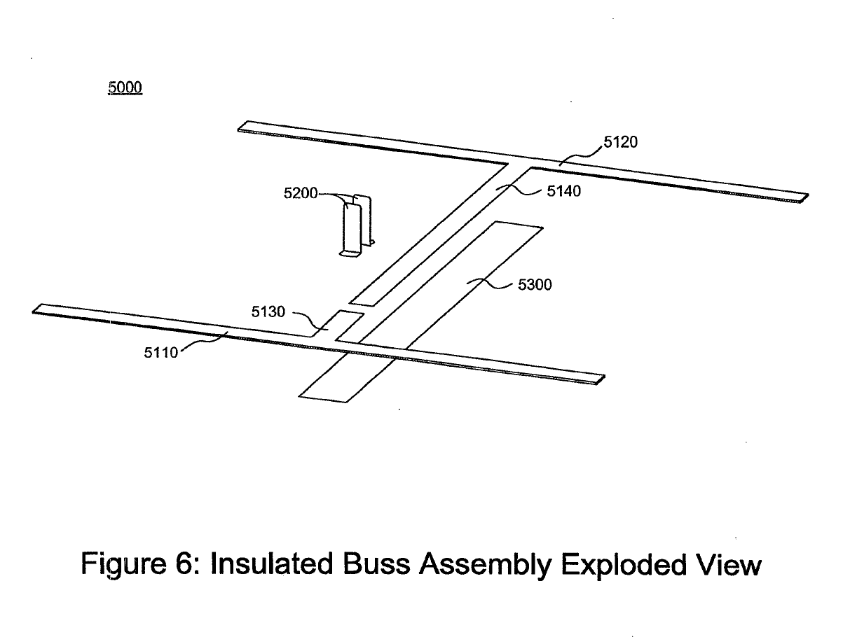

FIG. 6: Insulated Buss Assembly Exploded View

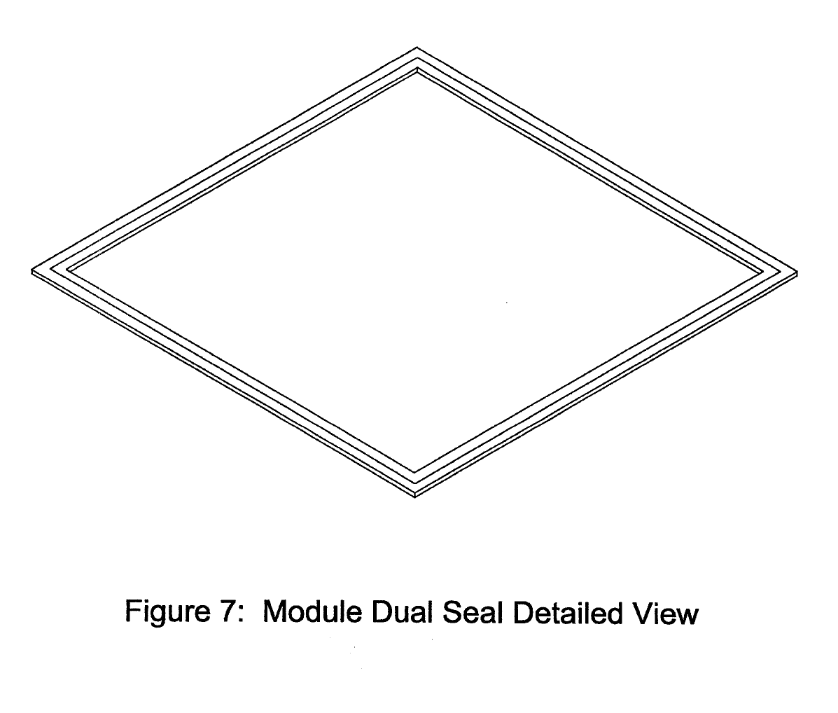

FIG. 7: Dual Seal Detailed View

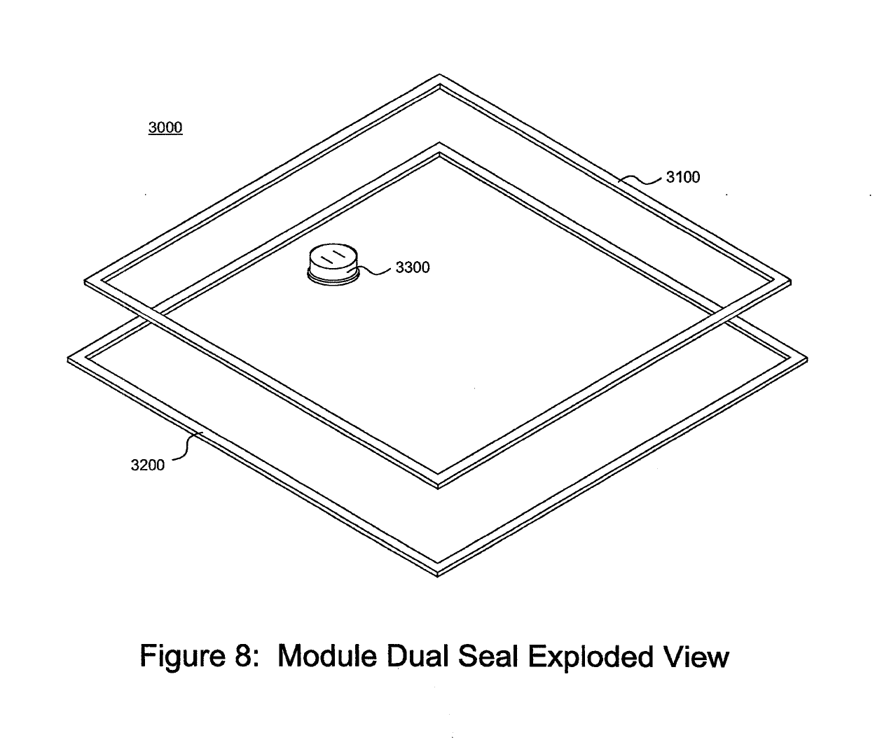

FIG. 8: Dual Seal Exploded View

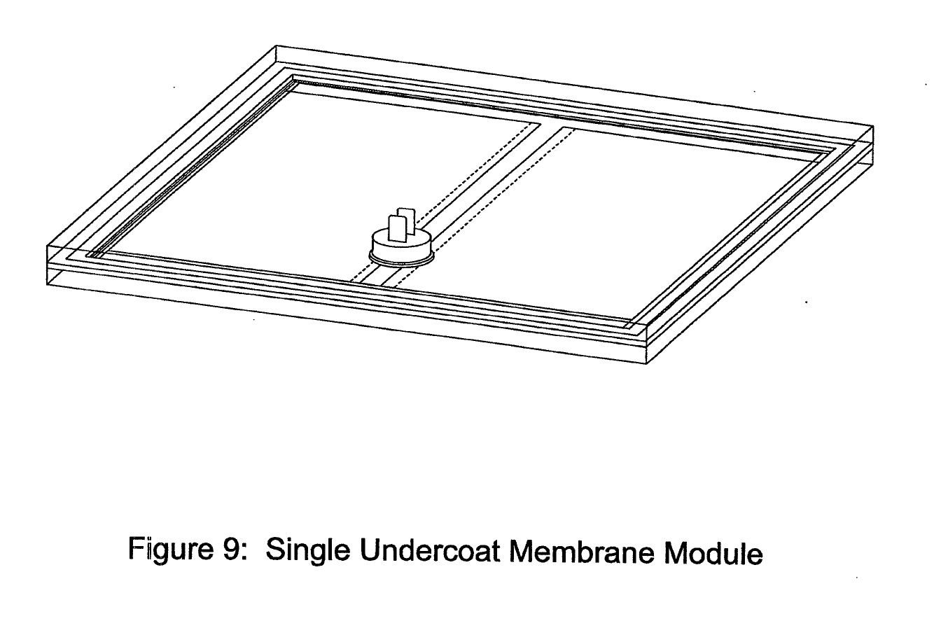

FIG. 9: Single Undercoat Membrane Module

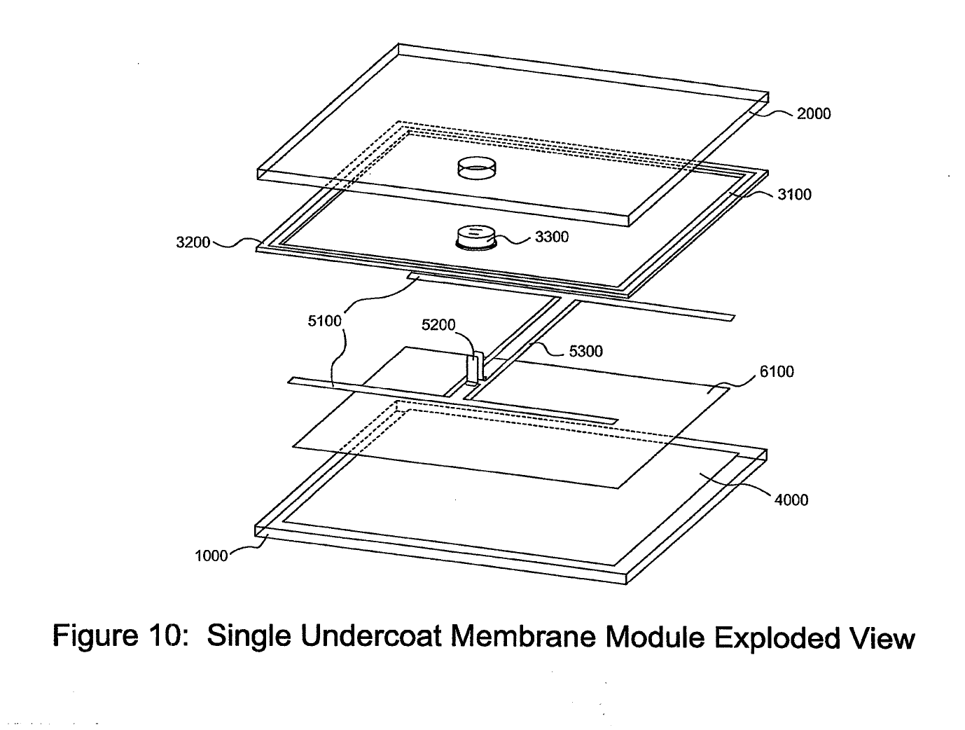

FIG. 10: Single Undercoat Membrane Module Exploded View

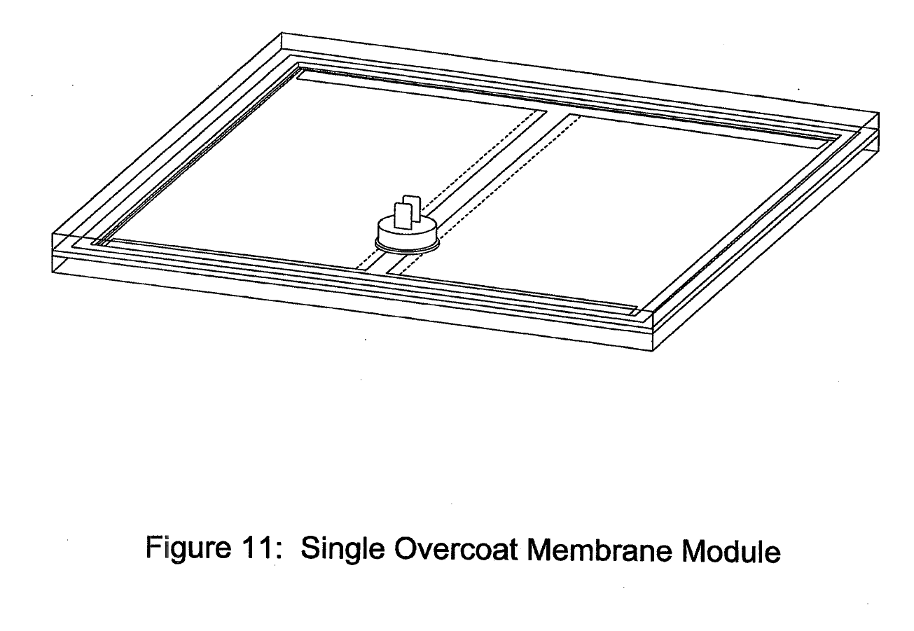

FIG. 11: Single Overcoat Membrane Module

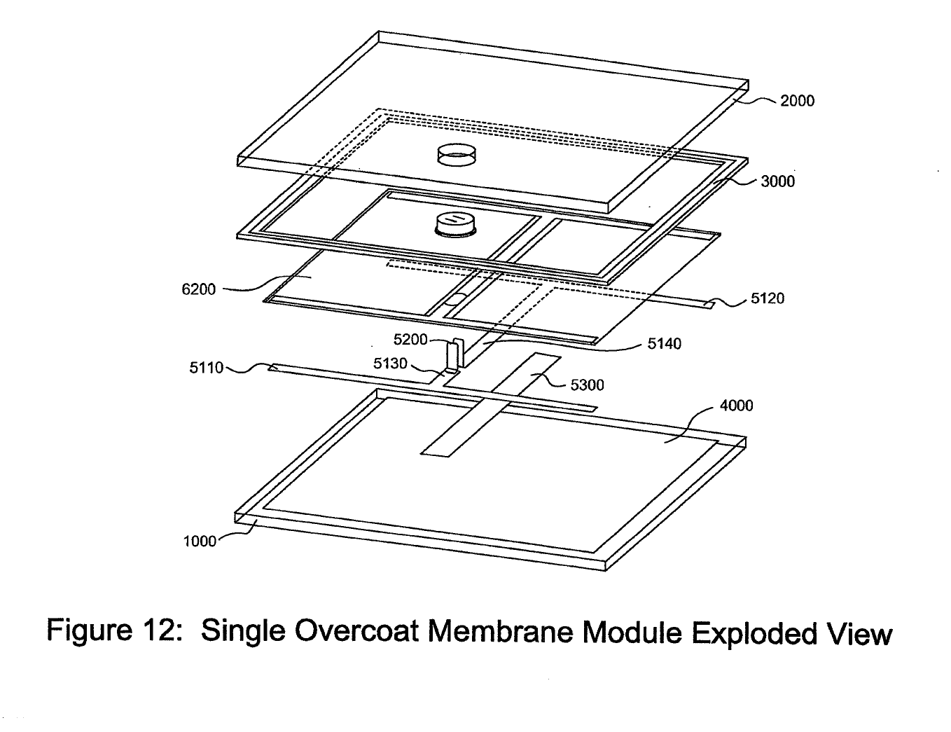

FIG. 12: Single Overcoat Membrane Module Exploded View

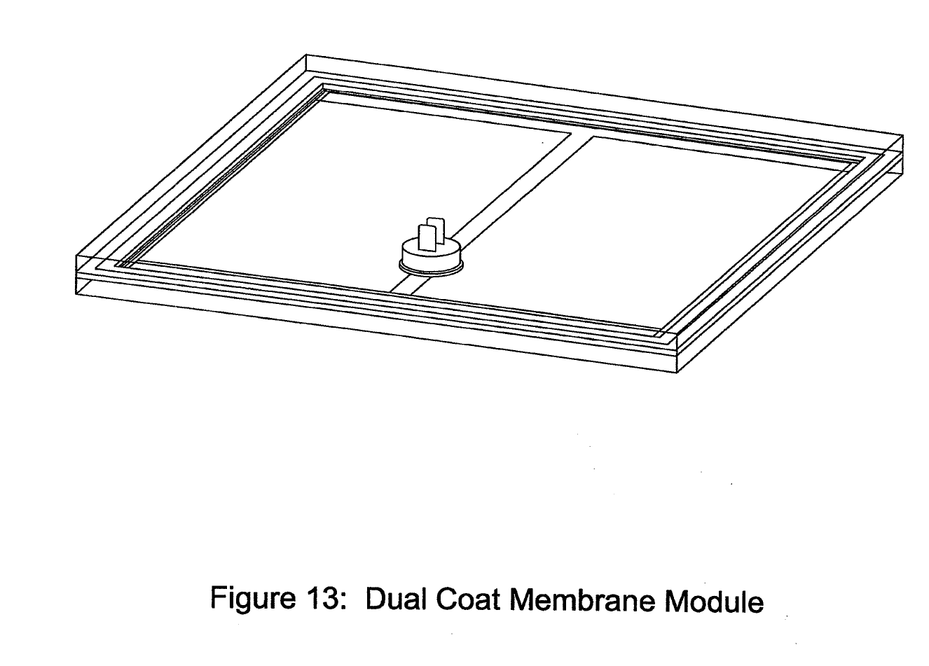

FIG. 13: Dual Coat Membrane Module

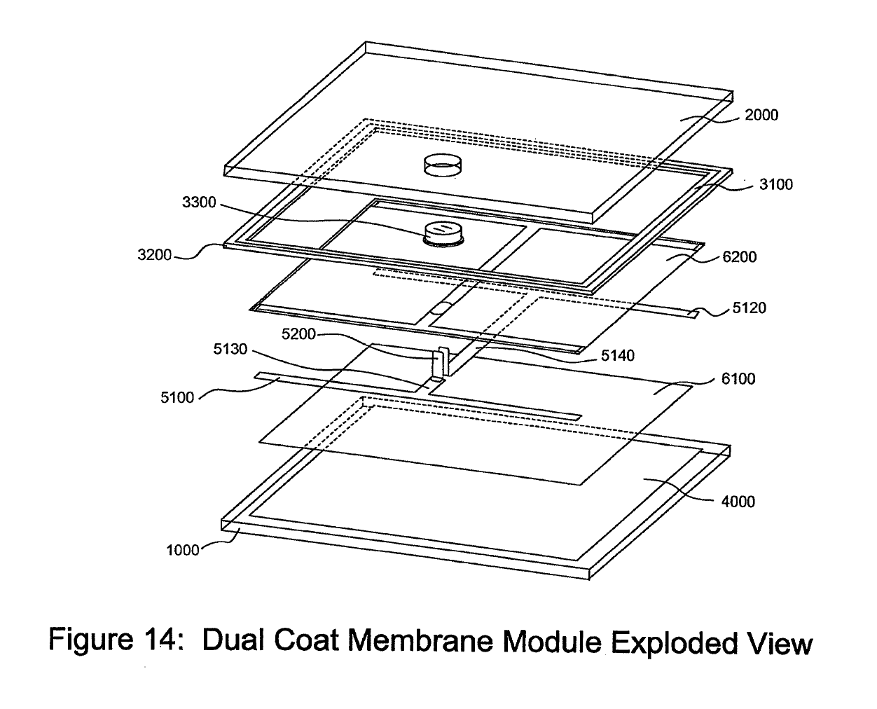

FIG. 14: Dual Coat Membrane Module Exploded View

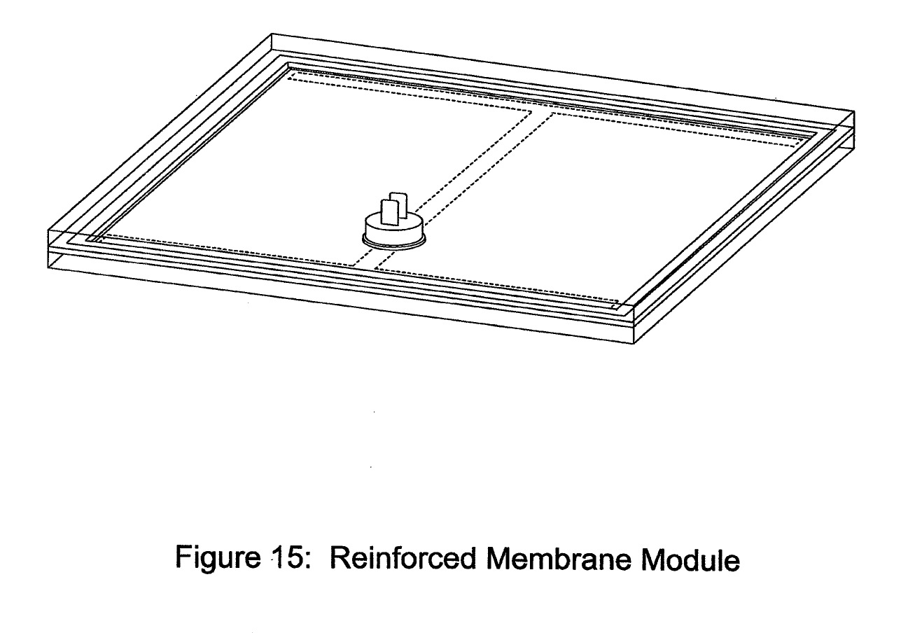

FIG. 15: Reinforced Membrane Module

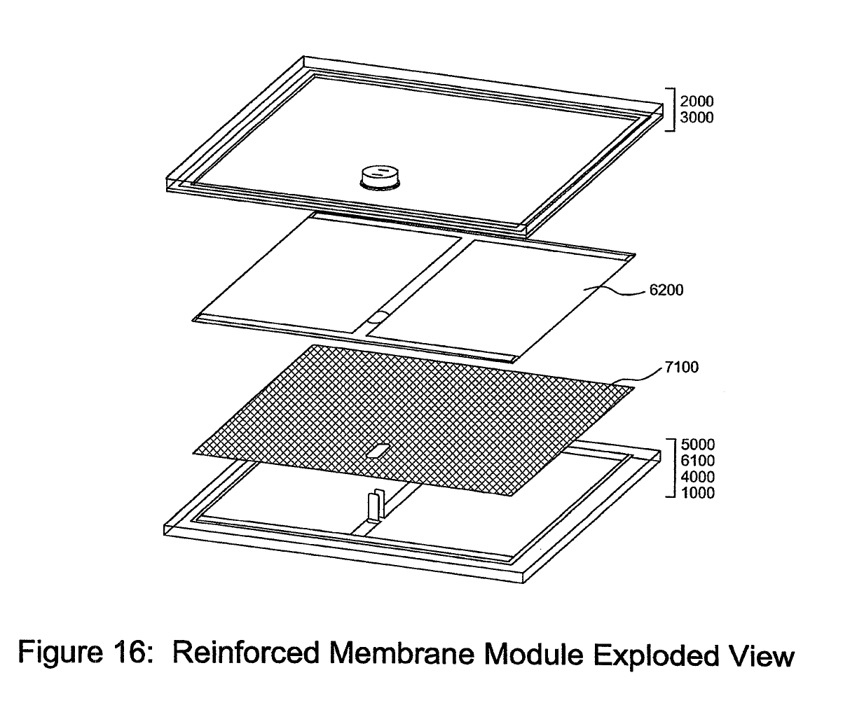

FIG. 16: Reinforced Membrane Module Exploded View

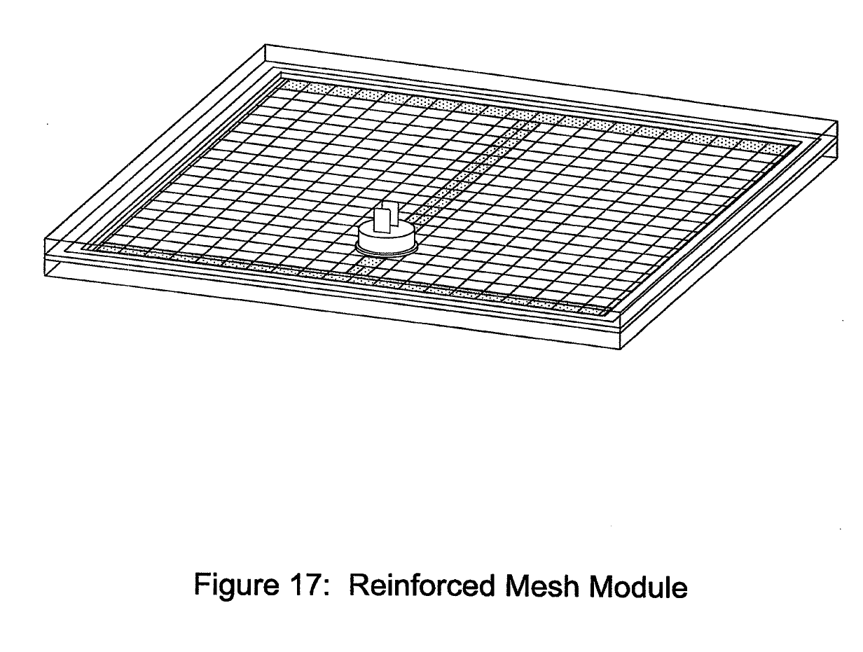

FIG. 17: Reinforced Mesh Module

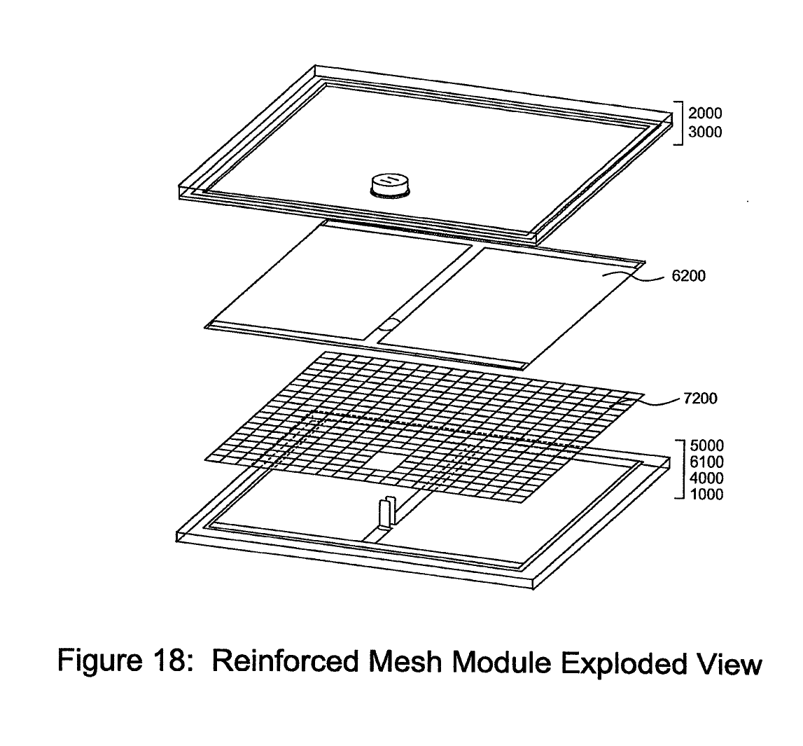

FIG. 18: Reinforced Mesh Module Exploded View

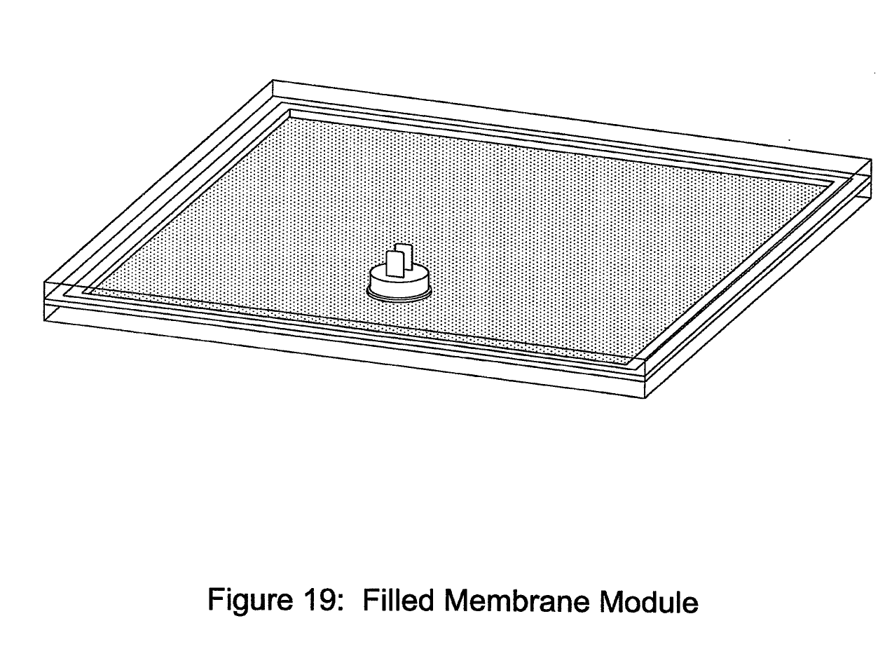

FIG. 19: Filled Membrane Module

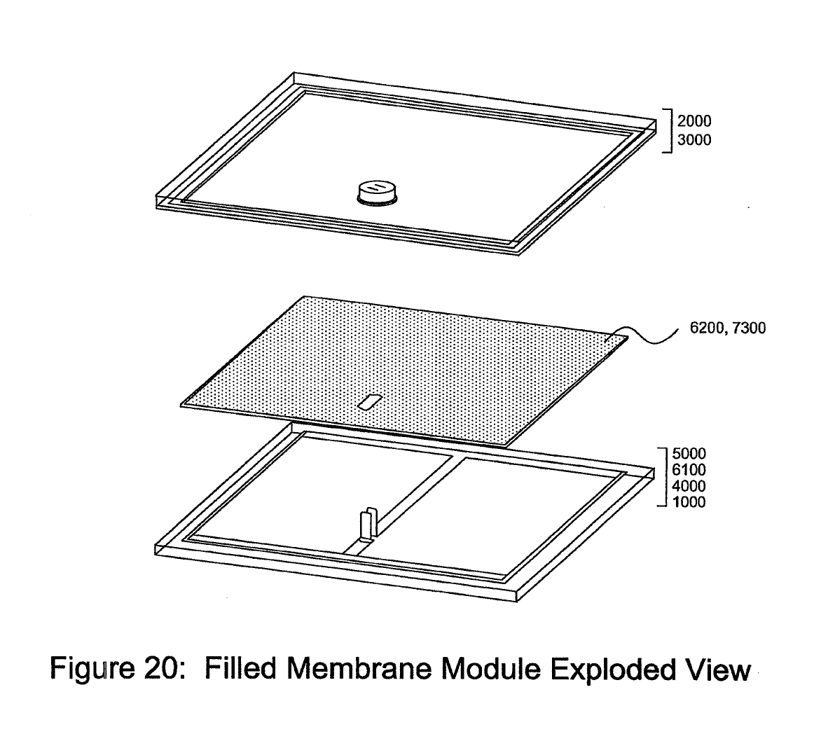

FIG. 20: Filled Membrane Module Exploded View

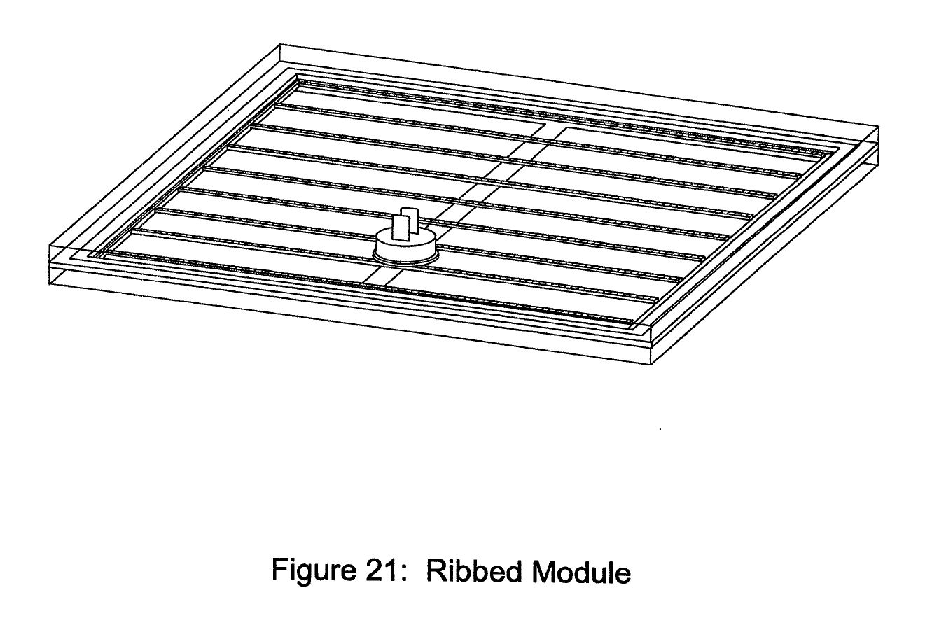

FIG. 21: Ribbed Module

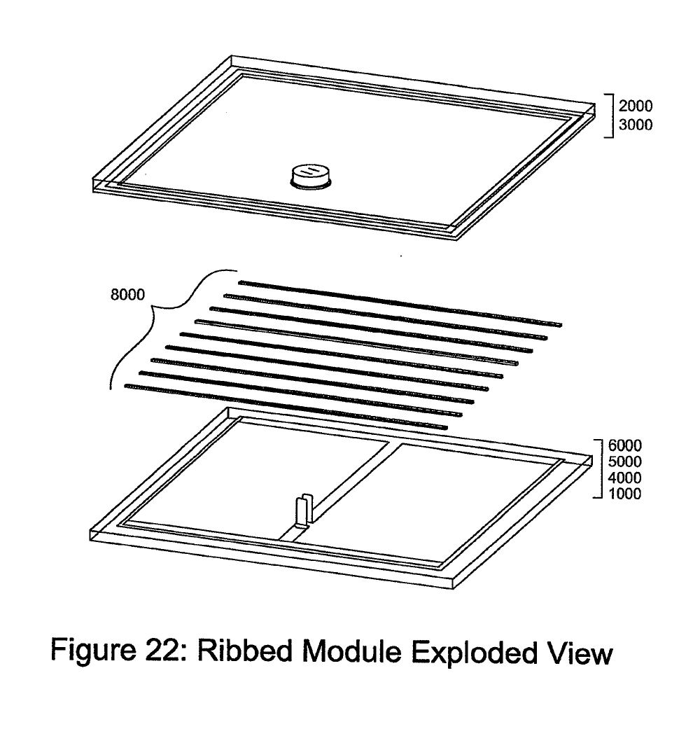

FIG. 22: Ribbed Module Exploded View

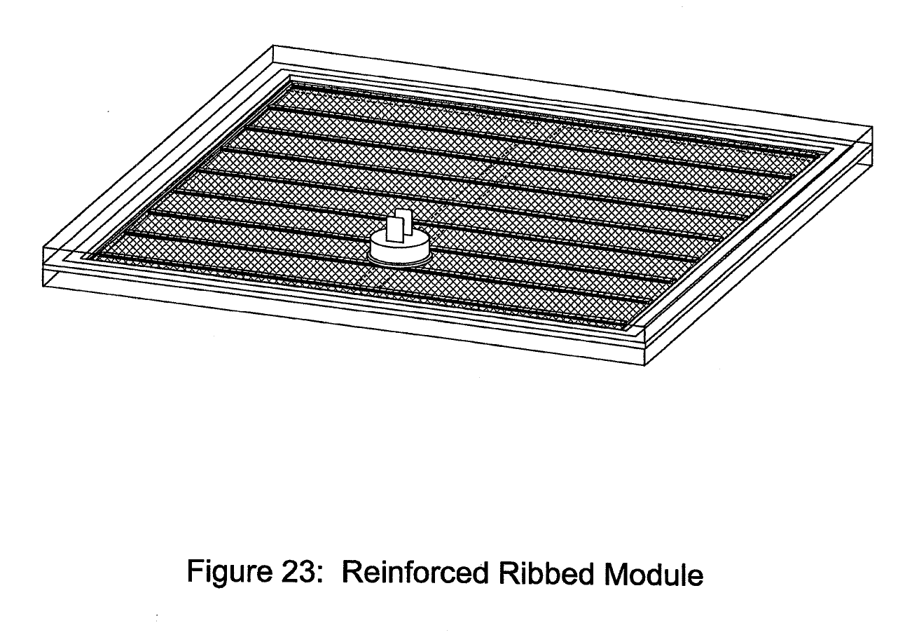

FIG. 23: Reinforced Ribbed Module

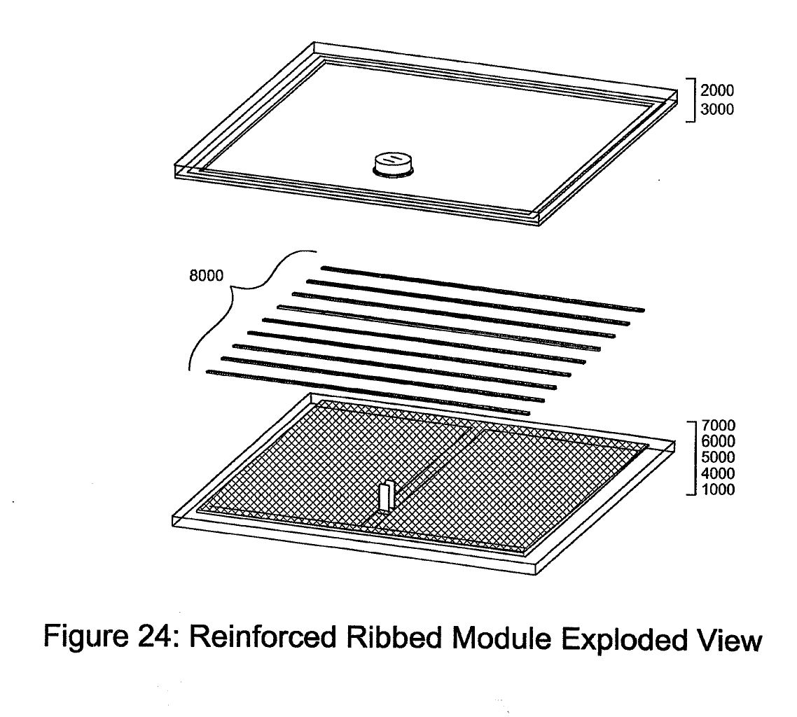

FIG. 24: Reinforced Ribbed Module Exploded View

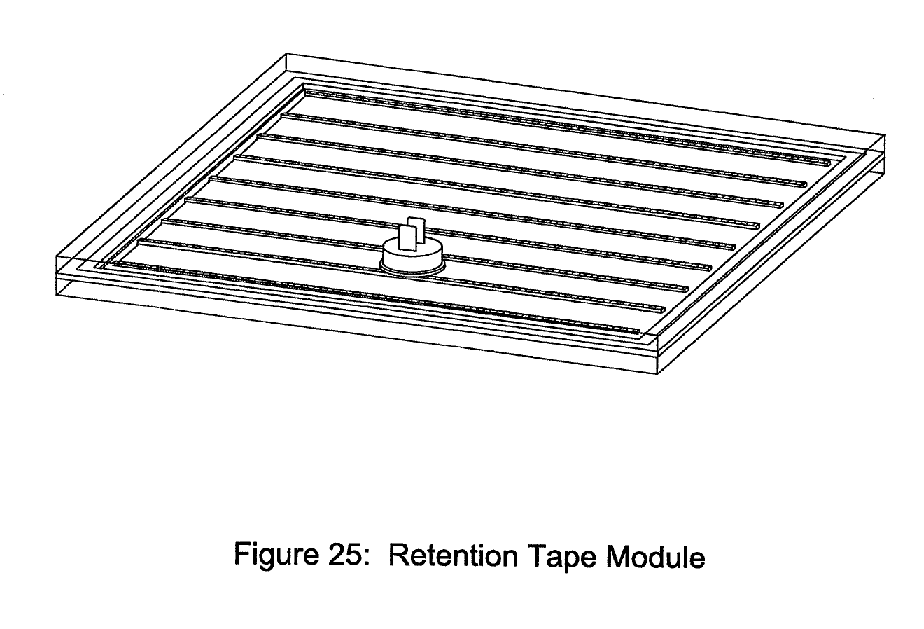

FIG. 25: Retention Tape Module

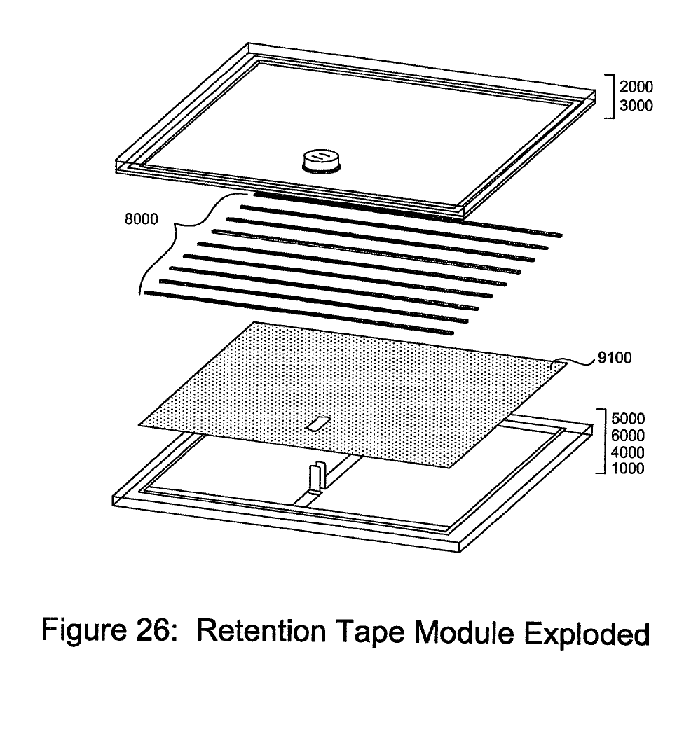

FIG. 26: Retention Tape Module Exploded View

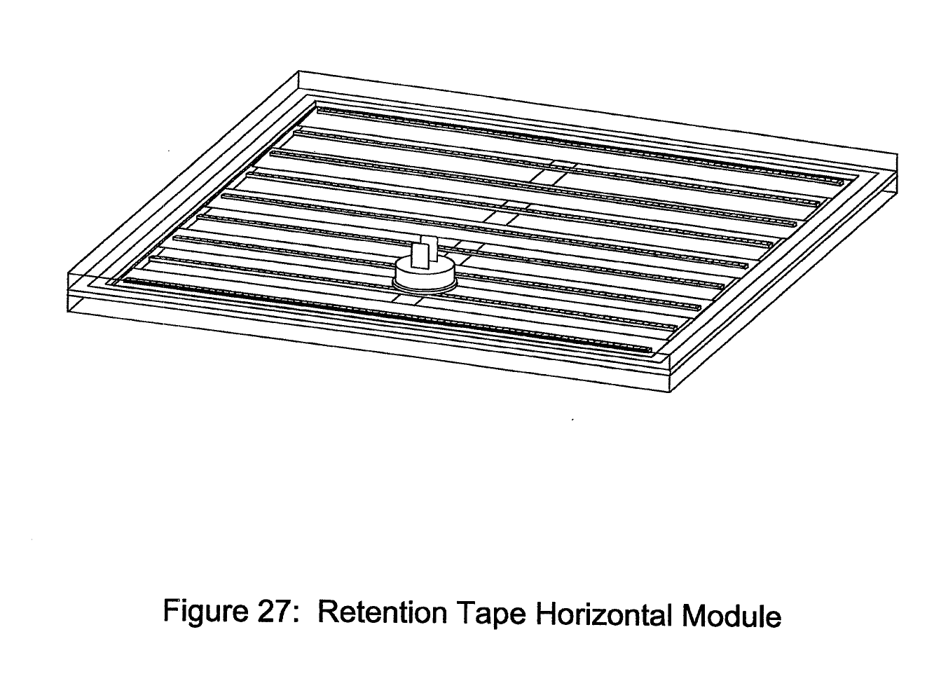

FIG. 27: Retention Tape Horizontal Module

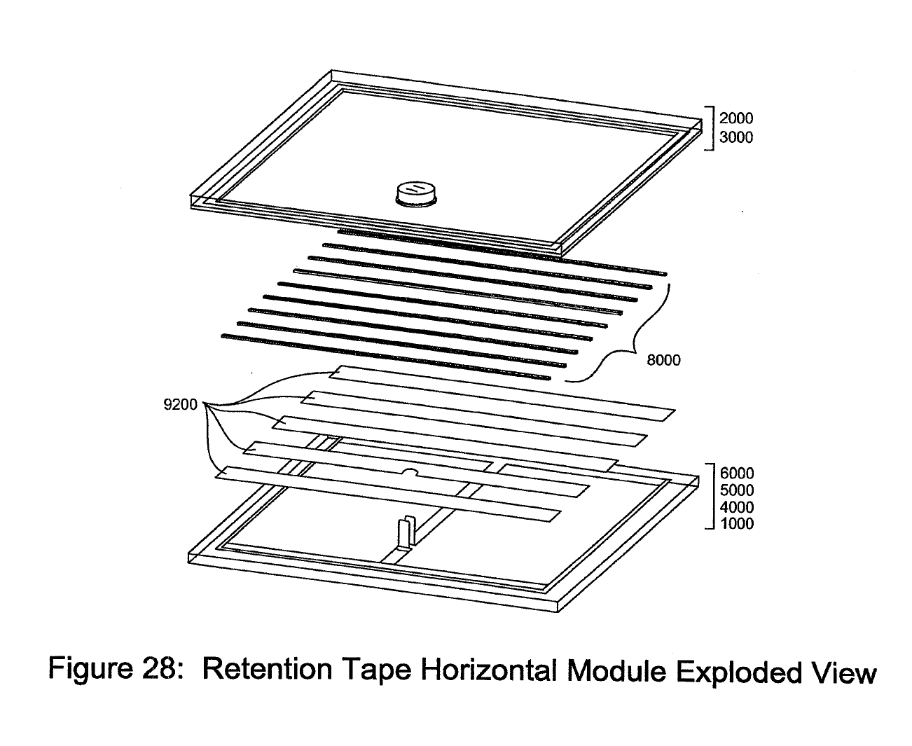

FIG. 28: Retention Tape Horizontal Module Exploded View

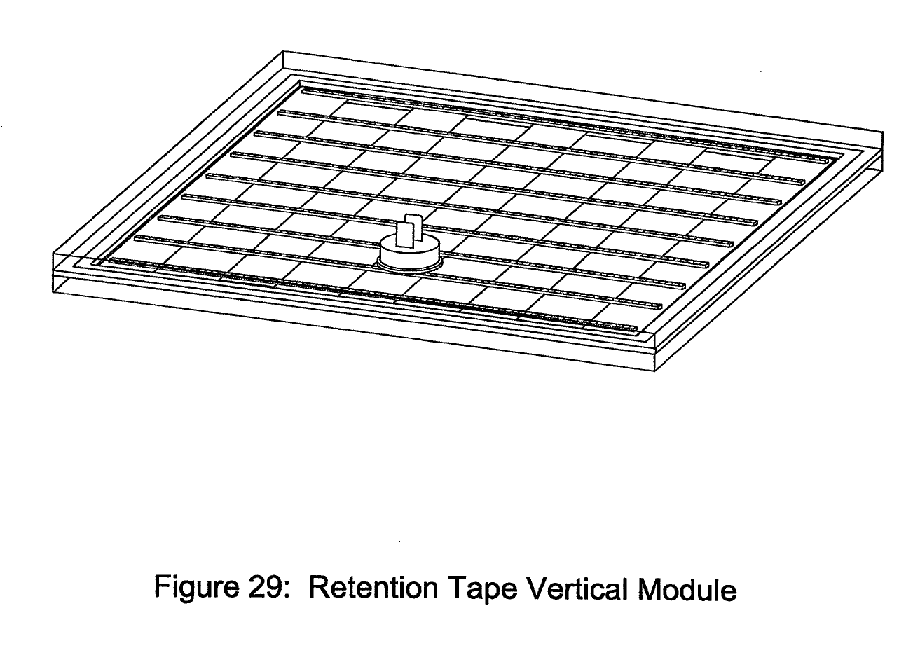

FIG. 29: Retention Tape Vertical Module

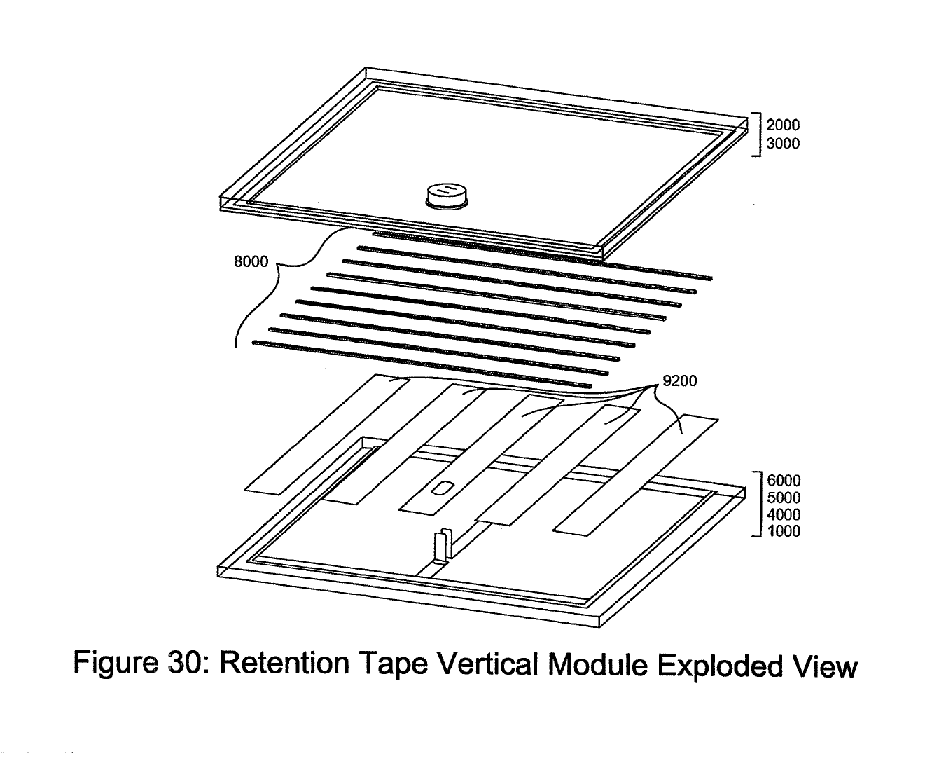

FIG. 30: Retention Tape Vertical Module Exploded View

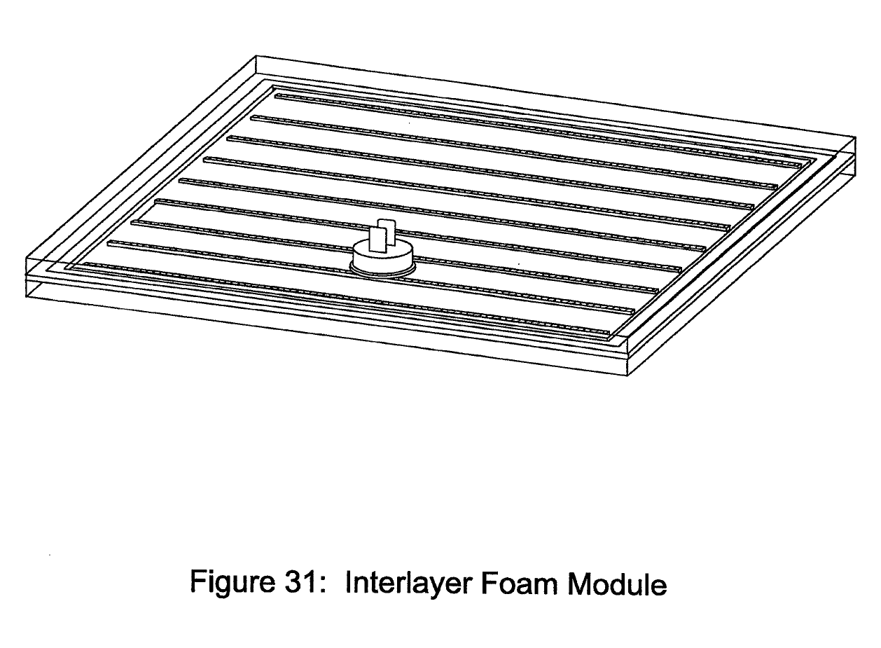

FIG. 31: Interlayer Foam Module

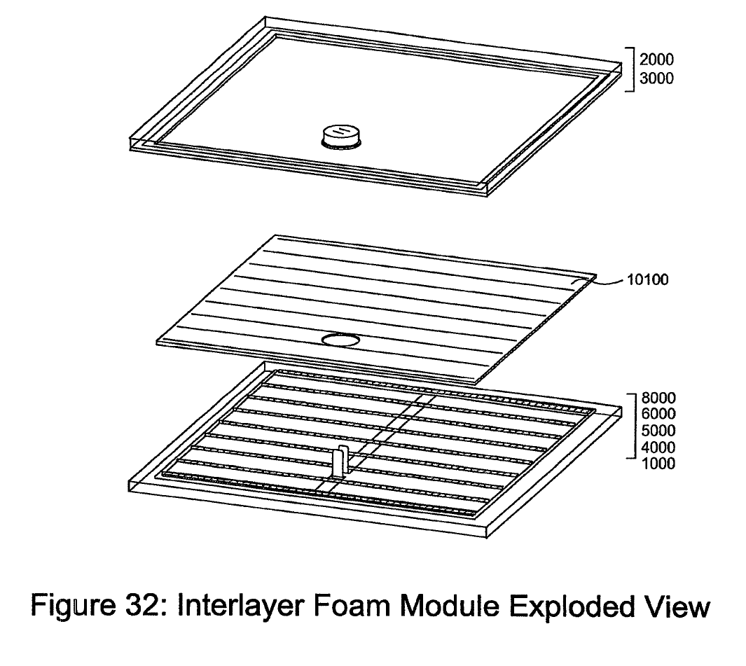

FIG. 32: Interlayer Foam Module Exploded View

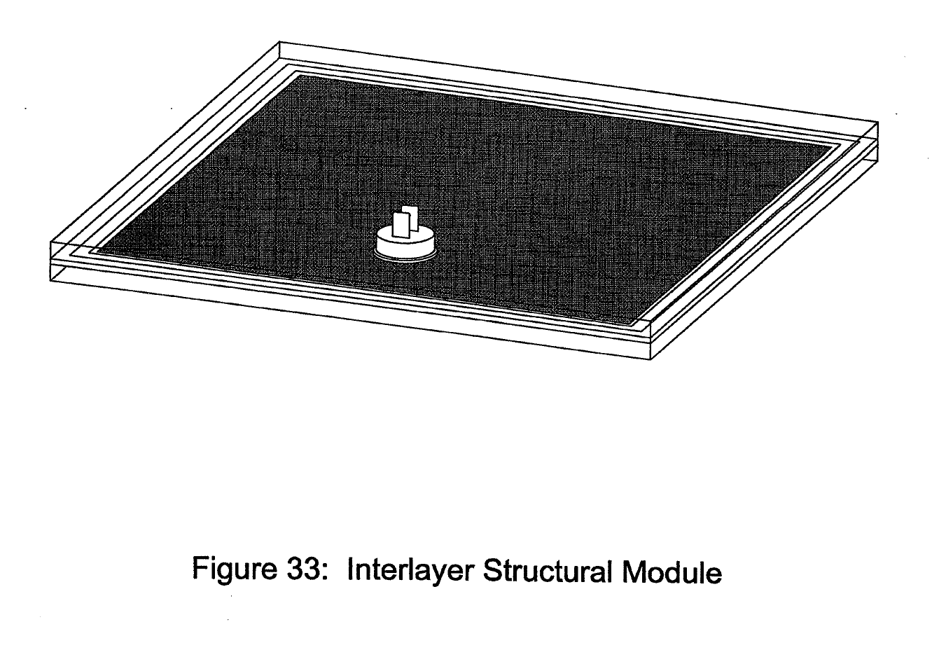

FIG. 33: Interlayer Structural Module

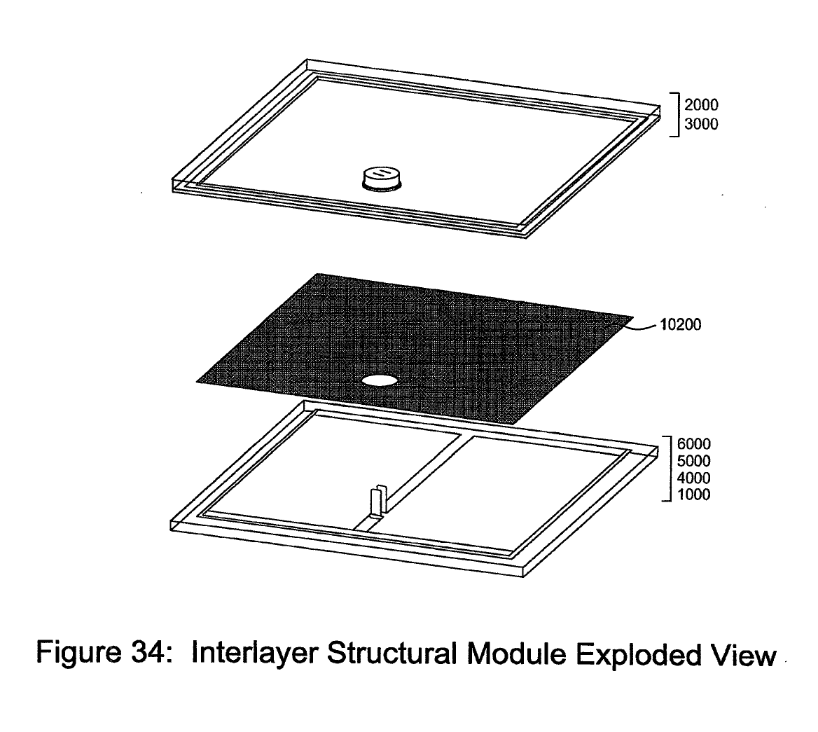

FIG. 34: Interlayer Structural Module Exploded View

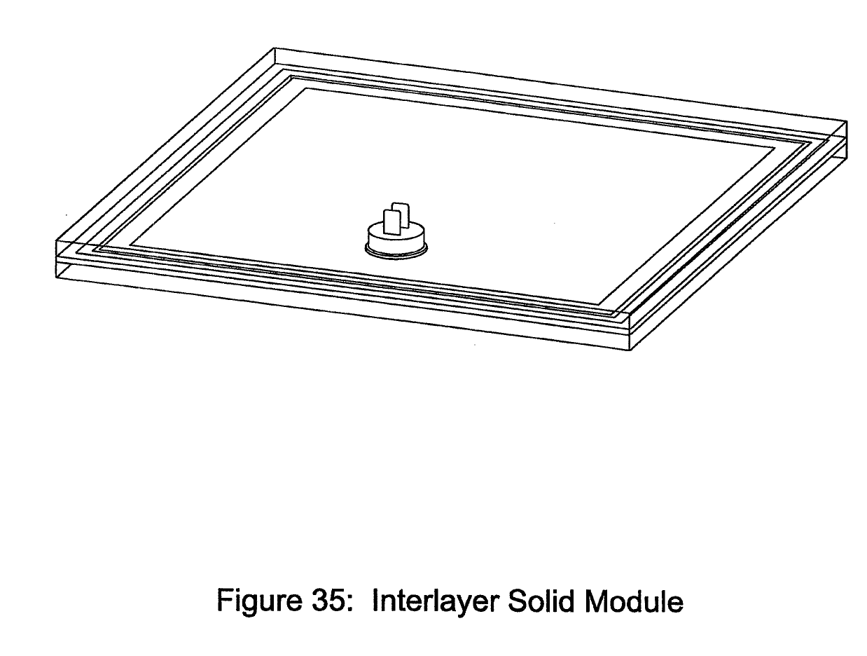

FIG. 35: Interlayer Solid Module

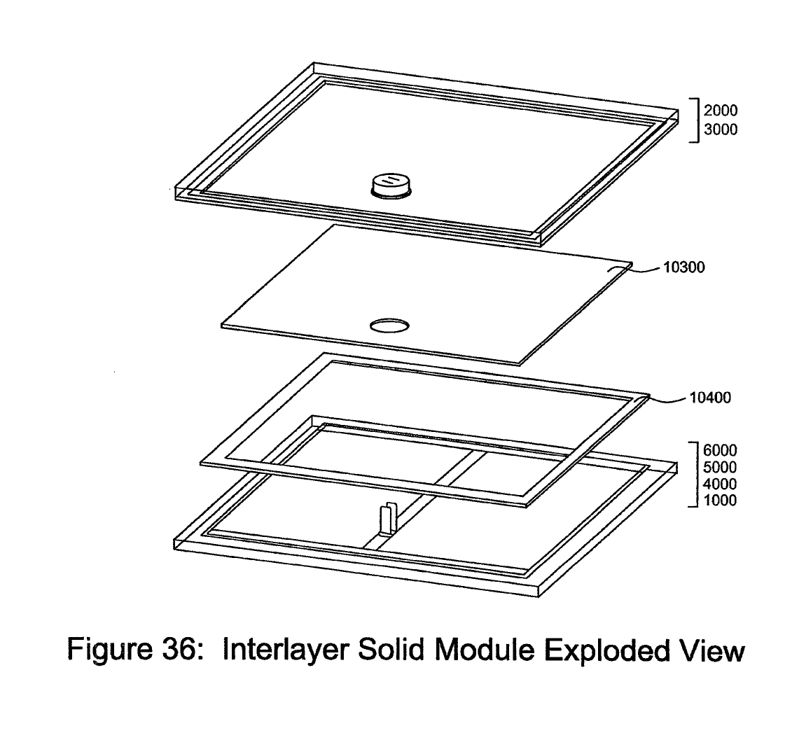

FIG. 36: Interlayer Solid Module Exploded View

### DETAILED DESCRIPTION

This specification discloses one or more embodiments that incorporate the features of this invention. The disclosed embodiment(s) merely exemplify the invention. The scope of the invention is not limited to the disclosed embodiment(s).

The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

The present invention describes encapsulation systems and methods for photovoltaic devices and improved module structures and methods for photovoltaic devices. Embodiments include photovoltaic encapsulation methods which incorporate a membrane (6000) positioned between a front substrate (1000) and back substrate (2000). The membrane (6000) can have a number of attributes which increase the photovoltaic module's reliability, performance and safety while minimizing cost and fabrication complexity. In addition, in some embodiments, other structures, such as a reinforcing scrim sheets (7100), mesh fibers (7200) or ribbing (8000), can be added between the front substrate (1000) and back substrate (2000) to improve the photovoltaic module's reliability, performance and safety. In some embodiments, additional structure(s), such as scrim sheets, mesh and fibers, can be incorporated into the membrane (6000), or separately positioned between the front substrate (1000) and back substrate (2000) to achieve various benefits.

In many exemplary embodiments of the present invention, the membrane (6000) can improve safety by helping prevent large shards of glass from being ejected from the module if breakage occurs. This is, at least in part, because the membrane (6000), and/or structural components, such as ribbing (8000) or interlayers (10000), may be connected with the front substrate (1000) and/or back substrate (2000). If breakage occurs, the broken pieces of the front substrate (1000) and/or back substrate (2000) are retained with the module's structure by the adhesive bond between the front substrate (1000) and/or back substrate (2000) and the membrane (6000) and/or other structural components. The membrane (6000) and other structural components may be used in combination or separately.

For example, in one embodiment a membrane (6000) may be adhered to the semiconductor photovoltaic structure (4000) formed on the front substrate (1000). If the front substrate (1000) should break, the membrane (6000) would add additional structure to retain the broken pieces of the photovoltaic structure (4000), and the front substrate (1000) upon which the photovoltaic structure (4000) is formed. In another embodiment, additional structural components could be connected with the membrane (6000) and the back substrate (2000). In yet another embodiment, additional structures could be connected with the photovoltaic structure (4000) and back substrate (2000). The additional structural components could be directly connected to or adhered to the semiconductor photovoltaic structure (4000) and back substrate (2000) or the additional structural components could be connected with the photovoltaic structure (4000), front substrate (1000) and back substrate (2000) through other elements. These additional connections improve structural integrity and assist in retaining pieces of the module if breakage occurs. Moreover, these additional structural components can also help prevent the loss of photovoltaic structure (4000) pieces coated with heavy-metal-containing materials, such as cadmium from the CdTe films.

Additional benefits of the present invention include the following: 1) protection of the back electrode metallization during module manufacturing and from potential contact with the back substrate (2000) under mechanical loading; 2) reinforcement of the buss bar assembly (5000), including buss tape adhesive junctions, preventing the buss-junctions from de-bonding; 3) providing an additional barrier against moisture vapor permeation to the photovoltaic structure (4000); 4) providing additional electrical insulation, 5) providing a desiccating medium to absorb moisture permeating through a seal between the front substrate (1000) and back substrate (2000); 6) providing added structural robustness to the module; 7) providing added thermal conduction through the interior of the module to reduce module temperature for improved module performance; and 8) improving overall module performance without significant cost or weight increases.

Many possible materials may be used to form a membrane (6000) consistent with the present invention. Membrane (6000) should be formed using materials with suitable mechanical properties for the planned implementation. Mechanical properties to consider include structural stability, shock absorption, and the ability to retain broken pieces and prevent them from being ejected if module breakage occurs. Other material properties of a membrane (6000), such as electrical insulation, thermal conduction, and the ability to resist vapor permeation are also important. Moreover, in addition to the properties of the formed membrane (6000), it is also important to consider material properties that affect the ability to properly form the membrane (6000) over the photovoltaic structure (4000). Those of skill in the art will be readily aware of membrane (6000) materials consistent with the present invention.

For some embodiments, the membrane (6000) may comprise a conformal polymer material. For example, the membrane (6000) may be comprised of a conformal film or coating. A conformal coating may be used to achieve advantages in module performance as well as module production efficiency. During production, a conformal coating membrane (6000) protects the photovoltaic structure (4000). During subsequent module build steps the membrane (6000) prevents damage to the fragile photovoltaic structure (4000). In field module applications, the conformal coating provides beneficial structural and electrical properties to protect the photovoltaic structure (4000) improving on the reliability of the module.

In other embodiments, the membrane (6000) may be comprised of a thermoplastic material. In yet another embodiment, the membrane (6000) may be comprised of a thermosetting material that is, for example, cured using chemical additives, ultraviolet radiation, electron beam or heat. In yet another embodiment, the membrane (6000) may be comprised of an elastic material, such as a thermosetting elastomer or a thermoplastic elastomer. By way of example, the membrane (6000) may be comprised of an urethane acetate, a thermally cured acrylic, a silicone RTV, and/or an epoxy. Those of ordinary skill in the art will be aware of membrane (6000) materials that may be selected consistent with the present invention. The membrane (6000) material selected may depend on many various factors readily understood by those of skill in the art, including, but not limited to, the material properties of the photovoltaic structure (4000), the other structural properties of the module, processing conditions, the environment in which the photovoltaic module will be used, cost, etc. For example, in order to improve takt time an UV curable urethane acetate may be used to form the membrane (6000).

In one embodiment, the membrane (6000) may be formed of an elastic material to add additional shock absorbing capability to the module. For example, many elastomeric polymers can undergo significant elongation under stress before failure. The elastic membrane could be applied directly to the back metal electrode of the photovoltaic structure (4000). The ability of the elastic membrane (6000) to flex during impact allows for some absorption of the impact load. Upon module breakage the elastic membrane (6000) bends with the fractured glass instead of breaking and hence provides a retention capability. Reinforcement materials could be utilized to provide an added degree of strength to the membrane (6000). In another embodiment, a silicone based conformal membrane (6000) could be put down in a soft thick coat.

A membrane (6000) can also provide a resilient surface which protects the photovoltaic structure (4000) during production, storage, transportation and end usage. The membrane (6000) adds durability for the photovoltaic module and adds an additional barrier to moisture permeation by substantially encapsulating the photovoltaic structure (4000). The membrane (6000) also aids in the electrical isolation of the scribe lines for the series interconnected photovoltaic cells of the thin film photovoltaic structure (4000).

A possible embodiment of the basic structure of a photovoltaic module is represented in FIG. 1 in which the photovoltaic is connected through a buss bar assembly (5000) to an exterior connection. An exploded view of a basic module construction is shown in FIG. 2. As depicted in FIG. 2, a photovoltaic structure (4000) is formed on a front substrate (1000). A buss bar assembly (5000) connects the photovoltaic structure (4000) to the exterior of the module. The buss bar assembly (5000) is made up of buss bar collectors (5100) attached to the leading and final edge cells of the photovoltaic series and terminating at the buss assembly connection (5200). The buss bar assembly (5000) is insulated from the remaining photovoltaic cells by a buss assembly insulator (5300). A detail of a possible buss bar collector configuration (5100) is illustrated in FIG. 3 and in the top view of the collectors in FIG. 4. The buss bar collectors configuration (5100) is made up of four sections: the anode edge collector buss (5110) and cathode edge collector buss (5120) are connected to the edge cells of the photovoltaic structure (4000). The anode edge collector buss (5110) is connected to the anode central main buss (5130) and cathode edge collector buss (5120) is connected to the cathode central main buss (5140).

FIG. 5 depicts one embodiment of how the buss bar collectors (5100) are incorporated into buss bar assembly (5000). As illustrated in the exploded view of the buss bar assembly (5000), FIG. 6, the anode central main buss (5130) and cathode central main buss (5140) terminate at the buss assembly connection (5200) to allow connection to an exterior wiring system (not shown). The buss assembly connection (5200) provides current to a back box (not shown) and external wires (not shown). Whereas the anode edge collector buss (5110) and the cathode edge collector buss (5120) are in contact with the edge photovoltaic cells of the module, the anode central main buss (5130) and cathode central main buss (5140) are insulated from the interior cells of the photovoltaic structure (4000) by a buss assembly insulator (5300). In one embodiment, the buss assembly insulator (5300) could be an insulating tape strip applied to the photovoltaic structure (4000). In another embodiment, the buss assembly insulator (5300) could be applied to the surface of the anode central main bus line (5130) and cathode central main buss line (5140) facing the photovoltaic structure (4000).

One embodiment of sealing the front and back of a basic photovoltaic module together is through the use of a dual perimeter seal. FIG. 7 illustrates a dual seal configuration consisting of an inner moisture vapor barrier seal (3100) and an outer liquid barrier edge seal (3200) as denoted in the exploded view in FIG. 8. One embodiment of a dual seal configuration would consist of a Polyisobutylene moisture barrier with a silicone edge seal. Also denoted in FIG. 8 is the connection seal (3300) that seals the buss connection. The connection seal could be also a Polyisobutylene moisture barrier if a liquid barrier such as silicone is used to seal subsequent back box connection.

In two different embodiments, the membrane (6000) can be applied prior to or after the application of the buss bar assembly (5000). If applied prior to the buss bar assembly (5000), the membrane (6000) can assist or substitute for the insulation of the central main buss collectors (5130, 5140) from the interior cells of the module. If applied after the application of the buss bar assembly (5000), the membrane (6000) electrically insulates all conductive regions in the module except for the buss assembly insulator (5300), adding additional safety. An embodiment comprising an electrically insulating membrane (6000) could also enable the use of a low cost polymer back sheet or a metal back sheet.

FIG. 9 illustrates an exterior view of one embodiment of the invention using a single membrane module construction in which an undercoat membrane (6100) is applied prior to the buss bar assembly (5000).

An exploded view of a single undercoat membrane (6100) construction is shown in FIG. 10. As depicted in FIG. 10, a photovoltaic structure (4000) is formed on a front substrate (1000). The undercoat membrane (6100) is applied prior to the basic module buss bar assembly (5000) and substantially encapsulates the photovoltaic structure (4000) by covering at least a majority of the interior cells of the module. As with the basic module's buss bar assembly (5000), the photovoltaic structure (4000) is connected to an anode edge collector buss (5110) and cathode edge collector buss (5120) of the buss bar assembly (5000). The undercoat membrane (6100) cannot cover the edge cells to which the edge collector buss (5110, 5120) must attach or the buss bar assembly would be insulated from the photovoltaic. The anode central main buss (5130) and cathode central main buss (5140) are connected to the anode edge collector buss (5110) and cathode edge collector buss (5120), respectively. The central main busses are routed across the undercoat membrane (6100) and are further connected to a buss assembly connection (5200). The anode central main buss (5130) and cathode central main buss (5140) are insulated from the photovoltaic structure (4000) by a buss assembly insulator (5300). In one embodiment, the buss assembly insulator (5300) could be an insulating tape strip applied to the photovoltaic structure (4000). In another embodiment, the buss assembly insulator (5300) could be applied to the surface of the anode central main buss line (5130) and cathode central main buss line (5140) facing the photovoltaic structure (4000). In a further embodiment, the buss assembly insulator (5300) could be omitted in embodiments in which the undercoat membrane (6100) is sufficient to insulate the anode and cathode central main collectors without the added insulation provided by the insulating tape.

FIG. 11 illustrates an exterior view of one embodiment of the invention using a single membrane module construction in which an overcoat membrane (6200) is applied after the buss bar assembly (5000).

An exploded view of a single membrane construction is shown in FIG. 12. As depicted in FIG. 12, as with the basic module, a photovoltaic structure (4000) is formed on a front substrate (1000). The two outer edge cells of the photovoltaic structure (4000) are connected to an anode edge collector buss (5110) and a cathode edge collector buss (5120) of a buss bar assembly (5000). The anode edge collector buss (5110) and cathode edge collector buss (5120) are connected to an anode central main buss (5130) and a cathode central main buss (5140), respectively, which are further connected to a buss assembly connection (5200). The anode central main buss (5130) and cathode central main buss (5140) are insulated from the photovoltaic structure (4000) by a buss assembly insulator (5300). In one embodiment, the buss assembly insulator (5300) could be an insulating tape strip applied to the photovoltaic structure (4000). In another embodiment, the buss assembly insulator (5300) could be applied to the surface of the anode central main buss (5130) and cathode central main buss (5140) facing the photovoltaic structure (4000). The buss assembly insulator (5300) is required in single overcoat embodiments of the invention since the membrane is not placed under the anode central main buss (5130) and the cathode central main buss (5140) and cannot provide insulation of the interior cells of the photovoltaic from the buss assembly. Unlike the single undercoat embodiments of the invention, the overcoat membrane (6200) covers the entire photovoltaic structure (4000) along with the complete buss bar assembly (5000) except for the buss assembly connection (5200), which remain uncoated to allow for external connection.

The buss bar assembly (5000) and photovoltaic structure (4000) are substantially encapsulated within a membrane overcoat (6200). In FIG. 12, the impressions of the buss bar assembly (5000) are shown in the conforming membrane overcoat (6200). An external seal assembly (3000) attaches the back substrate (2000) to the front substrate (1000). In this embodiment the external seal assembly (3000) comprises a dual seal, including a vapor barrier (3100) of butyl rubber or Polyisobutylene and edge seal (3200) of silicone, along with a butyl rubber or Polyisobutylene connection seal (3300). In the present embodiment, this seal arrangement creates an interior gap between the overcoat membrane coat (6200) and the back substrate (2000). The overcoat membrane (6200) can be desiccated to absorb moisture permeating through the external seal assembly (3000). The use of a dual seal arrangement is exemplary only and not intended to limit the present invention. Those skilled in the are will be readily aware that other sealing arrangements could be used consistent with the present invention.

In another embodiment, a membrane coating (6000) can be applied both before and after the application of the anode and cathode busses. FIG. 13 illustrates an exterior view of one embodiment of the invention using dual membrane module construction.

FIG. 14 shows an exploded view of a dual membrane construction. In FIG. 14 a photovoltaic structure (4000) is formed on a front substrate (1000). Adjacent to the photovoltaic structure (4000) is an initial undercoat membrane (6100) which substantially encapsulates the photovoltaic structure (4000) by covering the interior portion of the photovoltaic structure (4000) prior to application of the buss bar assembly (5000). The portions of the photovoltaic structure (4000) to which the anode and cathode edge collector busses (5110 and 5120) are to be attached are left uncoated. The initial undercoat membrane (6100) is applied prior to the buss bar assembly (5000) in order to both generally protect the photovoltaic structure (4000) and to insulate the photovoltaic structure (4000) from the anode central main buss (5130) and the cathode central main buss (5140).

The buss bar assembly (5000) and photovoltaic structure (4000) are further encased within an overcoat membrane (6200) to add further protection to the photovoltaic structure (4000) and to protect the buss bar assembly (5000). The impressions of the buss bar assembly (5000) are shown in the conforming membrane overcoat (6200). A secondary overcoat membrane (6200), applied after the buss bar assembly (5000), encapsulates and protects the electrical connections to the device. Those of ordinary skill in the art will realize that the buss assembly connection (5200) cannot be fully encapsulated for connection to a back electrical box (not shown). In some embodiments, the buss assembly connection (5200) will not be encapsulated by the overcoat membrane (6200). In other embodiments, the buss assembly connection (5200) may be encapsulated by the overcoat membrane (6200) for transport and assembly, but the portion of the overcoat membrane (6200) on the buss assembly connection (5200) is removed at some point before use. Variations and modifications consistent with present invention will be known to those of skill in the art.

In some embodiments, one or both of the membrane coatings (6100, 6200) can be desiccated to absorb moisture permeating through the external seal assembly (3000) over the life of the module. The two membrane coats (6100, 6200) can be of the same material or different materials in order to provide a combination of physical properties. In one embodiment, two polymers with differing chemistry may be used. In one exemplary embodiment, a secondary polymer elastic overcoat membrane (6200) could be used in conjunction with an initial conformal undercoat membrane (6100).

One of the benefits of the dual membrane constructions is that it could eliminate the separate production step of laying down insulating tape prior to the buss application. The initial undercoat membrane (6100) insulates the busses from the back electrode metallization on the photovoltaic structure (4000). Moreover, two applications of membrane material, both before and after the buss bar assembly (5000) application, incorporate the benefits of each of the separate applications.

A protective membrane (6000) applied over the photovoltaic structure (4000) prevents damage to the photovoltaic structure (4000) during subsequent module manufacturing processes. In the event the front substrate (1000) and photovoltaic structure (4000) need to be stored or transported prior to final module assemble, the membrane (6000) physically protects the photovoltaic structure (4000) and adds a barrier against moisture ingress. This membrane (6000) also encapsulates any heavy-metal-bearing material, such as CdTe, within the module. This further contains the heavy metal and helps prevent subsequent exposure to the heavy metals if the module is compromised. The addition of the membrane (6000) also improves electrical safety. Only a thin edge of the photovoltaic structure (4000) will be exposed upon module breakage. The module (6000) provides electrical isolation from the back electrode metallization and buss bar collectors (5100) surfaces.

In some embodiments, the undercoat membrane (6100) can be applied after the final isolation scribe of the photovoltaic structure (4000). The undercoat membrane (6100) could fill in the scribed regions preventing contamination of the scribe lines and possible shorting of the module.

The membrane coat(s) (6100 and/or 6200) could be applied using a number of acceptable methods. Application methods include brushing, spraying, precision spray, stenciling, screening, printing, vapor deposition, adhering, rolling or squeegee. Each membrane coat (6100, 6200) could be applied using the same application method, or the application method may vary between membrane coats. For example, referring to the dual membrane module assembly in FIG. 13, the initial undercoat membrane (6100) may be applied using squeegee while the overcoat membrane (6200) may be applied using spraying. In other embodiments, it may be preferential to use the same application method for the various membrane coats (6100, 6200). Those of skill in the art will realize variations and combinations of these application methods as well as other various application methods not discussed here.

In another embodiment of the invention, the membrane (6000) is formed by combining the membrane (6000) with membrane reinforcement (7000) such as a mesh or scrim layer. In one embodiment, the membrane reinforcement (7000) is applied between coats (e.g., 6100 and 6200) of the membrane (6000) or embedded within an individual layer of the membrane (6000). The membrane reinforcement (7000) can be used in conjunction with a membrane (6000) comprising various material properties (e.g., conformal coatings, elastomeric polymers, thermosets, etc.).

The addition of the membrane reinforcement (7000) enables a stronger layer of protection for the photovoltaic structure (4000), greater reinforcement of the photovoltaic module, and facilitates retention of the front substrate (1000) and back substrate (2000) on breakage. The reinforcement (7000) also constrains the membrane to alleviate thermal coefficient mismatch induced stresses in the photovoltaic structure. The membrane reinforcement (7000) could take the form of a mesh (7200) or scrim materials (7100). The membrane reinforcement (7000) could be comprised of fibers, strips, bands or thin rods and could be in a woven, uniaxial or random orientation in the module. Polymers or fine glass fibers are the preferred materials for constructing the membrane reinforcement (7000). Electrically conductive materials such as metals could cause arcing across the buss and back metal electrode.

In one embodiment, a photovoltaic module with a reinforced membrane (e.g., 6000 and 7000) could be constructed. First, an undercoat membrane (6100) would be applied over the photovoltaic structure (4000). The undercoat membrane (6100) is followed by the attachment of the collector buss to the anode and cathode cells. Next, the buss which run perpendicular to the interconnection scribing and which carry current to the back box and external wires are laid over the undercoat membrane (6100). The undercoat membrane (6100) acts as an electrical insulator between the photovoltaic structure's (4000) back metal electrode and the buss bar assembly (5000). The attachment of the buss is followed by the application of a layer of membrane reinforcement (7000) that is subsequently covered in a overcoat membrane (6200).

The overcoat membrane (6200) adds to the encapsulation of the photovoltaic structure (4000) and also encapsulates the buss bar assembly (5000). The addition of the membrane reinforcement (7000), after the buss application, forms an encapsulated module with just the buss assembly connection (5200) ends being accessible. This protects the fragile photovoltaic structure (4000) during subsequent manufacturing steps and during future operation. The composite membrane (6100, 7000, 6200) provides structural reinforcement to the front substrate (1000) on breakage. The subsequent back substrate (2000) and external seal assembly (3000) application are added for additional module structural strength and environmental protection.

FIG. 15 illustrates an exterior view of one embodiment of the invention using a reinforced dual membrane module construction in which a membrane reinforcement (7000) component is used to aid in retaining the front substrate (1000) if breakage occurs. The exploded view of the reinforced dual membrane construction, FIG. 16, shows an exploded view of a reinforced dual membrane construction in which the module is constructed as in dual membrane construction with a scrim sheet reinforcement (7100) placed between the undercoat membrane (6100) and overcoat membrane (6200) coats. The impressions of the buss bar assembly (5000) are shown in the conforming membrane overcoat (6200). The reinforcement scrim sheet reinforcement (7100) can be placed prior to or after the buss bar assembly (5000). FIG. 16 depicts the scrim sheet reinforcement (7100) being placed after the buss bar assembly (5000).

FIG. 17 shows an exterior view of one embodiment of the invention using a mesh reinforced dual membrane module construction in which a mesh sheet reinforcement (7200) is used in lieu of the scrim sheet reinforcement (7100).

FIG. 18 illustrates an exploded view of a mesh reinforced dual membrane construction in which the module is constructed as in dual membrane construction with a mesh sheet reinforcement (7200) placed between the undercoat membrane (6100) and overcoat membrane (6200). The impressions of the buss bar assembly (5000) are shown in the conforming membrane overcoat (6200). The mesh sheet reinforcement (7200) can be placed prior to or after the buss bar assembly (5000). FIG. 18 depicts the mesh sheet reinforcement (7200) being placed after the buss bar assembly (5000).

In another method, the membrane (6000) could be mixed with fine pieces of a membrane reinforcement (7000) material and the combination applied. Mixing fine pieces of membrane reinforcement (7000) with the membrane (6000) reduces the steps required during production and provides a greater degree of engineering properties to be designed into the composite membrane. FIG. 19 illustrates an exterior view of one embodiment of the invention using fiber filled reinforced dual membrane module construction in which the overcoat membrane (6200) is impregnated with a scrim impregnated reinforcement (7300). The exploded view of the construction in FIG. 20 shows a dual membrane construction with the overcoat membrane (6200) with a scrim impregnated reinforcement (7300).

In still another embodiment of the invention, a structural component such as polymer ribbing (8000) is incorporated between the module back substrate (2000) and the photovoltaic structure (4000). These ribbed element(s) (8000) are spread periodically across the area of the module.

FIG. 21 shows an exterior view of one embodiment of the invention using a ribbed membrane module construction. These ribbed elements (8000) perform a number of functions including reducing the module operating temperature by increasing thermal heat transfer from the front substrate (1000), which is exposed to the sun, to the back substrate (2000). Additional module strength is achieved through the use of structural polymer ribbing (8000). The ribbing (8000) spans the gap between the photovoltaic structure (4000), membrane (6000) (whether conformal coatings or elastic membranes) and back substrate (2000). In doing so, the ribbing (8000) provides distribution of the module loading between the front substrate (1000) and back substrate (2000). By spanning the gap between the front and back of the module, the external seal assembly (3000) dual seal module is able to take on the mechanical characteristics of a laminated structure. The polymer ribbing (8000) could be applied over the module busses to maintain buss adhesion and prevent debonding of the buss from the metallization. Placement of the ribbing over the connection between the edge and central busses adds to the integrity of the junction.

FIG. 22 shows an exploded view of a ribbed construction in which the module is constructed as in the single or dual membrane construction with polymer ribs (8000) placed between the membrane (6000) and the back sheet (2000). The ribbing (8000) provides a conductive thermal path between the front substrate (1000) and back substrate (2000) of the module and provides structural support in the gap between the front and back of the module.

In order to achieve the mechanical and thermal benefits from the polymer ribbing (8000), the ribbing material must be compliant—conforming to both surfaces of the module when the back substrate (2000) is assembled to the module structure. It is beneficial that the ribbing (8000) have some bonding with the adjoining surfaces and that that the ribbing (8000) material compresses to ensure an intimate contact when the back substrate (2000) is assembled to the module. The structural ribbing (8000) can be composed of the same polymer as the vapor barrier (3100), of the dual edge seal, to facilitate manufacturing.

Compliant material may not sufficiently assist in the retention of the front substrate (1000) and back substrate (2000) on breakage. To compensate for the compliant nature of the ribbing (8000), reinforced conformal and elastic membrane constructions can be used to provide additional substrate (1000, 2000) retention capability. An exterior view of one embodiment of the invention using reinforced ribbed membrane module construction is shown in FIG. 23.

FIG. 24 shows an exploded view of a reinforced ribbed construction in which the module is constructed with a membrane reinforcement construction (7000) with polymer ribs (8000) placed between the membrane (6000) and the back substrate (2000). It will be understood by those of skill in the art that the membrane (6000) does not have to be included. The ribbing (8000) provides a conductive thermal path between the front substrate (1000) and back substrate (2000) of the module as well as provides structural support in the gap between the front and back of the module. In some embodiments, the ribbing (8000) will provide thermal conduction paths distributed across the internal surfaces of the front (1000) and back (2000) substrates. For example, the ribbing (8000) can be arrayed periodically over the photovoltaic structure (4000) in order to provide distributed conduction paths from the front substrate (1000), through the photovoltaic structure (4000), through the ribbing (8000) and to the back substrate (2000). In some embodiments, the ribbing can also be connected with (directly or indirectly) with the front substrate (1000) and back substrate (2000) to assist in retention of pieces during breakage. By using a ribbing (8000) that is arrayed periodically it will assist in retaining pieces across the entire surfaces of the front substrate (1000) and back substrate (2000).

Either the ribbing (8000) or membrane (6000), or both, can be desiccated to absorb moisture permeating through the exterior seal assembly (3000) over the life of the module. In one embodiment, a polymer ribbing (8000) material can contain desiccant to protect the photovoltaic structure (4000) from moisture damage. Since the ribbing (8000) has a high surface area it provides additional moisture absorption capability.

In addition, the structural nature of the ribbing (8000) provides benefits over a loose desiccant between the front substrate (1000) and back substrate (2000). For example, when moisture permeates through the external seal and only a loose desiccant is used, the moisture will cause the loose desiccant to clump. The clumps can contact portions of the buss bar assembly (5000) or the photovoltaic structure (4000) and cause a short. When the desiccant is incorporated with a structural component such as the ribbing (8000) it can help eliminate the problems caused by the loose desiccant.

A desiccated member within the module structure provides for absorption of moisture permeating through the external seal assembly (3000) over the life of the module. The amount of desiccant required is dependent on the permeability of the external seal assembly (3000) and the desired life of the module. In one embodiment, module desiccation can be obtained by incorporating desiccant into the ribbing (8000) and/or adding desiccant to the membrane (6000). Since the materials selected for the membrane (6000) may be different than those selected for the edge seal (3200) and vapor barrier (3100), the membrane (6000) material may have a different permeability than the edge seal (3200) and vapor barrier (3100) material. Desiccation of these layers is done depending on their level of permeability.

In another embodiment of the invention, a retention sheet (9000) of suitable properties may be used in conjunction with, instead of, or as the membrane (6000) to promote retention of the front substrate (1000) and back substrate (2000) if the module breaks. In one embodiment, the retention sheet (9000) is a polymer sheet that may be used in conjunction with an undercoat membrane (6100) or overcoat membrane (6200), such as a conformal polymer coat. For example, if the undercoat membrane (6100) is comprised of a more brittle material, a retention sheet (9000) may be used as the overcoat membrane (6200) added to aid retention of broken pieces should breakage occur. In this respect, a retention sheet (9000) allows for a broader range of membrane (6000) materials to be used while still providing the advantages of piece retention when a module breaks. In another embodiment, the functionality of the undercoat membrane (6100) or the overcoat membrane (6200) or both membranes could be performed by one or more retention sheets (9000) used in lieu of the undercoat membrane (6100) or the overcoat membrane (6200). In one embodiment, the retention sheet (9000) may be unrolled and applied (e.g., adhered) to cover the photovoltaic structure (4000).

In one exemplary embodiment, the retention sheet (9000) may be a retention tape sheet (9100). These retention tape sheet(s) (9100) can be comprised of thin polymer film(s) with adhesive on one side. These retention tape sheets (9100) can retain glass shards upon module breakage and protect the photovoltaic structure (4000) from abrasion during manufacturing and module usage. As with the conformal membrane coatings, the retention sheet (9000) could be applied directly to the photovoltaic structure's (4000) back metal electrode. In another embodiment, the retention sheet(s) (9000) can be applied on top of either the undercoat membrane (6100) or overcoat membrane (6200), or both. The retention sheet (9000) could be applied in the form of single sheet that substantially covers and encapsulates the photovoltaic structure's (4000) surface by covering at least a majority of the photovoltaic cells. The retention sheet (9000) could be in the form of a simple film with adhesive on one side, such as those available from 3M, Poli-Film and Mitsubishi. In some embodiments, the retention sheet (9000) could be reinforced with fibers to increase strength. The retention sheet (9000) may be comprised of polymer materials such as polyethylenes, polyesters, polyurethanes, and paper with suitable dielectric properties, such as those used in transformer windings. The retention sheet (9000) may be used adjacent to the buss bar assembly (5000).

Now referring to FIG. 25, illustrated is an exterior view of one embodiment of the invention using ribbed module construction in which a retention tape sheet (9100) is used to retain the front and back substrates (1000, 2000) on breakage.

FIG. 26 shows an exploded view of a tape retention construction in which the retention tape sheet (9100) is placed upon the membrane (6000). The retention tape sheet (9100) does not fill the gap between the front and back of the module. Ribbing (8000) may be employed to span, and in some cases fill, this gap and to provide thermal and structural support. In one embodiment, a ribbing (8000) can be used in conjunction with a membrane (6000), membrane reinforcement (7000), and retention sheet (9000). In other embodiments, one or more of those elements will not be used. Those of skill in art will be aware of many various embodiments and combination of these structures consistent with the present invention. In many embodiments, the ribbing (8000) would be the last of these materials applied in sequence, and would be applied on top of these other elements.

In another embodiment, referring now to FIG. 27, retention tape strips (9200) may be used to retain the front and back substrate (1000, 2000) on breakage. FIG. 28 shows an exploded view of a parallel strip construction in which the retention tape strips (9200) are placed upon the membrane (6000) parallel to the buss alignment.

In some embodiments, the retention tape strips (9200) take the form of polymer tape strips which are placed periodically or in a pattern suitable to retain glass shards under module breakage. In addition to a material savings, using retention tape strips (9200) enables the use of readily available tape dispensing machines for application.

FIG. 29 shows a ribbed module construction in which retention tape strips (9200) are used to retain the module pieces on breakage in lieu of a retention tape sheet (9100). The exploded view, in FIG. 30, shows the retention tape strips (9200) placed upon the membrane (6000) perpendicular to the edge buss alignment. In variations of both the parallel (see FIG. 28) and perpendicular (see FIG. 30) placements, the retention tape strips (9200) can be placed in a preferential orientation or orientations to the plane of the buss as a series of strips or an interlacing of strips.

In still another embodiment of the invention, a foam interlayer (10100) structural component can be used to provide a light weight, uniform filler for the air space inside the module, adjacent to the back substrate (2000). An adhesive may be used to adhere the foam to the inner module structure. In one embodiment the foam interlayer (10100) may be a porous foam that can be sheathed with sheets of adhesive bearing materials or adhesive can be spray applied to allow even better adhesion of the foam. In one embodiment, the adhesive may be the retention tape sheet (9100) or retention tape strips (9200). The foam interlayer (10100) converts the dual seal module into a structure that has similar mechanical and thermal properties as a laminated module. The foam interlayer (10100) provides uniform load dissipation through the module with minimal added weight and provides substantially uniform thermal conduction between the front substrate (1000) and back substrate (2000) surfaces, lowering module operating temperatures. The foam interlayer (10100) can provide substantially uniform thermal conduction by distributing the thermal conduction over the entire surfaces of the front (1000) and back substrates (2000). When adhered, the foam interlayer (10100) provides additional retention for both the front (1000) and back substrate (2000) on breakage. In some embodiments, the foam interlayer (10100) could be applied directly to the photovoltaic structure's (4000) back metal electrode. This may be as a substitute for the undercoat membrane (6100), used in conjunction with the undercoat membrane (6100) but in lieu of a second conformal coating, or added in addition to the membrane (6100 and/or 6200). In another embodiment, the foam interlayer (10100) could be used in conjunction with any or all of the membrane (6000), membrane reinforcement (7000), ribbing (8000), and retention sheet (9000). Those of skill in the art will realize the various embodiments of each of these components, and the various combinations of components, that may be used consistent with the present invention.

FIG. 31 shows an exterior view of one embodiment of the invention using a foam interlayer (10100) module construction in which a foam sheet is used to span, and in at least some cases fill, the gap between the front and back of the module. The exploded view of the construction is shown in FIG. 32 in which the module is constructed with a foam interlayer (10100) placed in conjunction with ribbing (8000) between the membrane (6000) and the back substrate (2000). It will be understood by those of skill in the art that the membrane (6000) does not have to be included.

The materials that comprise the foam interlayer (10100) can be selected to include desiccants. For example, a foam interlayer (10100) with high moisture permeability combined with desiccant would allow for moisture that permeates through the external seal assembly (3000) to be absorbed. Materials with improved thermally conductivity and/or reinforcement characteristics could be incorporated with the foam interlayer (10100).

For certain embodiments it may be beneficial for the foam interlayer (10100) to be cut into specific shapes prior to module assembly. For example, if the foam interlayer (10100) was used in conjunction with ribbing (8000), the foam interlayer (10100) could be cut to fill in the regions around the ribbing (8000). The addition of ribbing (8000) could aid in thermal transfer if the foam interlayer (10100) porosity prevented adequate thermal transfer. Desiccated polymer material (not shown) can be used along the perimeter of the foam interlayer (10100) to aide in absorption of moisture permeating through the external seal assembly (3000).

FIG. 33 shows an exterior view of one embodiment of the invention using a structural interlayer (10200) construction in which a structural interlayer (10200) is used to span, and in some cases fill, the gap between the front and back of the photovoltaic module. The structural interlayer (10200) can be designed to provide thermal, structural and desiccating properties. In one embodiment, the structural interlayer (10200) can be formed using a foam fabricated in a corrugated or embossed configuration to reduce weight and materials usage. The corrugated or embossed configuration could also be formed using a polymer pre-cast layer that could contain reinforcement and desiccant. The exploded view of the structural interlayer module (10200) construction, FIG. 34, shows the structural interlayer (10200) between the membrane (6000) and the back substrate (2000). Those of skill in the art will realize the various embodiments of each of these components, and the various combinations of components, that may be used consistent with the present invention.

For situations requiring a highly robust module structure, high density foam or pre-cast structural interlay with a very low void content could be used to effectively form a solid interlayer (10300) that is inserted during module construction. FIG. 35 illustrates an exterior view of one embodiment of the invention using a solid interlayer (10300) to span the gap between the front and back of the module. The solid interlayer (10300) improves thermal and, structural module properties but requires a desiccated perimeter. FIG. 36 shows an exploded view of a interlayer construction in which the solid interlayer (10300) and a desiccated interlayer perimeter (10400) are positioned between the membrane (6000) and the back substrate (2000).

As shown in FIG. 36, a gap around the perimeter of the solid interlayer (10300), between the edge seal (3200) and the solid interlayer (10300) could be present. This gap can be filled and/or spanned using a solid interlayer perimeter (10400). The solid interlayer perimeter (10400) includes desiccant to absorb any moisture that permeates through the edge seal (3200). One advantage of the solid interlayer (10300) is the ability to embed a scrim for added strength. In some embodiments, the solid interlayer (10300) may be comprised of solid durable polymer or polymer/scrim to provide increased overall module robustness. If module breakage occurs at higher loading, the solid interlayer (10300) can retain module integrity. Moreover, if the solid interlayer (10300) is connected with the front substrate (1000) and back substrate (2000) (directly or through other structures) the solid interlayer (10300) can assist in retaining pieces on breakage.

In conclusion, while various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with scope and spirit of the following claims and their equivalents.

What is claimed is:

1. A photovoltaic module comprising:
a front substrate;
a photovoltaic structure attached to the front substrate, wherein the photovoltaic structure comprises at least one photovoltaic cell;
a back substrate, wherein the back substrate is spaced apart from the photovoltaic structure; and
a structural component, wherein the structural component is located between the back substrate and the photovoltaic structure.

2. The photovoltaic module of claim 1 wherein the structural component comprises ribbing.

3. The photovoltaic module of claim 2 wherein the ribbing is arrayed periodically over the photovoltaic structure.

4. The photovoltaic module of claim 2 wherein the ribbing comprises Polyisobutylene.

5. The photovoltaic module of claim 2 wherein the ribbing comprises a compliant material.

6. The photovoltaic module of claim 1 wherein the structural component comprises foam.

7. The photovoltaic module of claim 6 wherein the foam is selected from the group comprising porous foam, corrugated foam, and embossed foam.

8. The photovoltaic module of claim 1 wherein the structural component comprises a solid interlayer.

9. The photovoltaic module of claim 8 wherein the solid interlayer comprises a high density foam.

10. The photovoltaic module of claim 1 wherein the structural component comprises foam and ribbing.

11. The photovoltaic module of claim 1 wherein the structural component incorporates desiccant.

12. The photovoltaic module of claim 1 wherein the structural component is configured to connect with the front substrate and the back substrate.

13. The photovoltaic module of claim 12 wherein the structural component is configured to provide distributed thermal conduction between the front substrate and the back substrate.

14. The photovoltaic module of claim 1 wherein the structural component is configured to connect with the front substrates in order to retain the front substrate during module breakage.

15. The photovoltaic module of claim 1 wherein the structural component is configured to connect with the back substrate in order to retain the back substrate during module breakage.

16. The photovoltaic module of claim 1 wherein the structural component is configured to provide load dissipation through the photovoltaic module.

17. The photovoltaic module of claim 8 further comprising:
an external seal assembly, wherein the external seal assembly is configured to form a seal between the front substrate and the back substrate; and
a solid interlayer perimeter, wherein the solid interlayer perimeter is desiccated and wherein the solid interlayer perimeter is located between the external seal assembly and the solid interlayer.

18. The photovoltaic module of claim 1 further comprising:
an external seal assembly, wherein the external seal assembly is configured to form a seal between the front substrate and the back substrate.

19. The photovoltaic module of claim 1 further comprising:
a membrane, wherein the membrane and the front substrate substantially encapsulate the photovoltaic structure.

20. The photovoltaic module of claim 19 further comprising:
at least one retention tape strip, wherein the at least one retention tape strip adheres to the membrane.

21. The photovoltaic module of claim 1 further comprising:
at least one retention tape strip, wherein the at least one retention tape strip adheres the structural component to the back substrate.

22. A method for making a photovoltaic module, the method comprising:
forming a photovoltaic structure on a front substrate, wherein the photovoltaic structure comprises at least one photovoltaic cell;
positioning a structural component between the photovoltaic structure and a back substrate; and
connecting the back substrate with the front substrate using a seal, wherein the structural component is configured to provide distributed thermal conduction from the front substrate to the back substrate.

23. The method of claim 22 wherein the structural component comprises ribbing.

24. The method of claim 22 wherein the structural component comprises foam.

25. The method of claim 22 further comprising:
connecting the structural component with the front substrate in order to retain the front substrate during breakage.

26. The method of claim 25 wherein connecting the structural component with the front substrate comprises:
adhering the structural component to the photovoltaic structure.

27. The method of claim 24 wherein connecting the structural component with the front substrate comprises:
applying a membrane on the photovoltaic structure, wherein the membrane and the front substrate substantially encapsulate the photovoltaic structure; and
attaching the structural component to the membrane.

28. The method of claim 22 further comprising:
connecting the structural component with the back substrate in order to retain the back substrate during breakage.

29. The method of claim 28 wherein connecting the structural component with the back substrate comprises:
adhering a first side of retention tape to the structural component; and
adhering a second side of the retention tape to the back substrate.

30. A photovoltaic module comprising:
a front substrate;
a photovoltaic structure attached to the front substrate;
a back substrate, wherein the back substrate is spaced apart from the photovoltaic structure to form a gap; and
a structural component, wherein the structural component spans the gap between back substrate and the photovoltaic structure.

31. The photovoltaic module of claim 30 wherein the structural component is configured to provide distributed thermal conduction between the front substrate and the back substrate.

32. The photovoltaic module of claim 30 wherein the structural component is configured to provide distributed load dissipation through the photovoltaic module.

33. The photovoltaic module of claim 30 wherein the structural component is configured to retain the front and the back substrates during breakage.

34. The photovoltaic module of claim 30 wherein the structural component fills the gap between back substrate and the photovoltaic structure.
